(19) United States
(12) Patent Application Publication
(10) Pub. No.: US 2022/0320379 A1
(43) Pub. Date: Oct. 6, 2022

(54) MICRO LED DISPLAY MANUFACTURING DEVICE AND METHOD OF MANUFACTURING MICRO LED DISPLAY

(71) Applicant: POINT ENGINEERING CO., LTD., Asan (KR)

(72) Inventors: Bum Mo AHN, Suwon (KR); Seung Ho PARK, Hwaseong (KR); Sung Hyun BYUN, Hwaseong (KR)

(21) Appl. No.: 17/254,519

(22) PCT Filed: Sep. 8, 2020
(86) PCT No.: PCT/KR2020/012098

§ 371 Date: Dec. 21, 2020

(30) Foreign Application Priority Data
Oct. 4, 2019 (KR) 10-2019-0123269

(51) Int. Cl. H01L 33/48; H01L 33/00; H01L 27/15

(52) U.S. Cl. CPC H01L 33/486; H01L 33/005; H01L 27/156

(57) ABSTRACT

Proposed are a micro LED display manufacturing device and a method of manufacturing a micro LED display. More particularly, proposed are a micro LED display manufacturing device and a method of manufacturing a micro LED display, wherein a hybrid transfer process is used.

### TECHNICAL FIELD

The present disclosure relates to a micro LED display manufacturing device and a method of manufacturing a micro LED display, wherein hybrid transfer is used.

### BACKGROUND ART

Currently, the display market remains dominated by LCDs, but OLEDs are quickly replacing LCDs and emerging as mainstream products. In the current situation in which display makers are rushing to participate in the OLED market, micro light-emitting diode (hereinafter, referred to as ‘micro LED’) displays have emerged as another type of next generation display. Liquid crystal and organic materials are the core materials of LCDs and OLEDs, respectively, whereas the micro LED display uses 1 μm to 100 μm of LED chips themselves as a light emitting material.

Such micro LEDs may be fabricated on a growth substrate and may undergo a transfer process to be transferred to a substrate (e.g., a carrier substrate, a temporary substrate, or a circuit board).

In the related art, as a transfer method for transferring micro LEDs fabricated on a growth substrate, a fluid transfer method for transferring micro LEDs to a substrate (e.g., a carrier substrate, a temporary substrate, or a circuit board) using a fluid, or a head transfer method for holding micro LEDs using a head and transferring the same to a substrate (e.g., a carrier substrate, a temporary substrate, or a circuit board) has been used.

However, since the micro LEDs of the growth substrate are transferred to the substrate using one of the fluid transfer method and the head transfer method, it is impossible to perform a transfer process using the advantages of the two methods at the same time, resulting in defective products due to the disadvantages of each transfer method.

Accordingly, the applicant(s) of the present disclosure intends to propose a new transfer method that has not been considered in the related art.

### DOCUMENTS OF RELATED ART

### Patent Document

(Patent Document 1) Korean Patent Application Publication No. 10-2017-0026957

(Patent Document 2) Korean Patent Application Publication No. 10-2018-0115584

### DISCLOSURE

### Technical Problem

Accordingly, the present disclosure has been made keeping in mind the above problems occurring in the related art, and an objective of the present disclosure is to provide a micro LED display manufacturing device and a method of manufacturing a micro LED display, wherein micro LEDs are effectively transferred through a hybrid transfer method in which a fluid transfer method and a head transfer method are combined.

Another objective of the present disclosure is to provide a micro LED display manufacturing device and a method of manufacturing a micro LED display, wherein micro LEDs are effectively transferred to a carrier substrate as the carrier substrate is not located only inside a fluid during a fluid transfer process, but is lifted above the fluid surface.

Still another objective of the present disclosure is to provide a micro LED display manufacturing device and a method of manufacturing a micro LED display, wherein foreign matter generated due to differences in space and time during transfer of micro LEDs is prevented.

### Technical Solution

In order to accomplish the above objectives, the present disclosure provides a micro LED display manufacturing device, including: a carrier part including a carrier substrate onto which micro LEDs of the same type inserted into a storage tank in which a fluid is stored are held at positions spaced apart a predetermined pitch distance; and a transfer head part transferring the micro LEDs on the carrier substrate to a pixel substrate outside the storage tank.

Furthermore, the carrier substrate may be configured to be lifted while forming an inclination angle with the fluid of the storage tank.

Furthermore, the carrier substrate may include: a seating recess in which each of the micro LEDs is seated; a non-seating region where no micro LEDs are seated; and a vacuum hole formed in a lower portion of the seating recess.

Furthermore, when the fluid is hydrophilic, a hydrophobic layer may be formed on a surface of the non-seating region, and when the fluid is hydrophobic, a hydrophilic layer may be formed thereon.

Furthermore, the micro LED display manufacturing device may further include: a dryer drying a surface of the carrier part.

Furthermore, the micro LED display manufacturing device may further include: a vision tester provided above the carrier part, wherein the vision tester may test whether each of the micro LEDs is seated in a seating recess.

Furthermore, the micro LED display manufacturing device may further include: a sliding part supporting a lower portion of the carrier part as the lower portion of the carrier part slides therealong.

Furthermore, the micro LED display manufacturing device may further include: a driving part lifting the carrier part while maintaining the inclination angle constant.

Furthermore, the micro LED display manufacturing device may further include: a driving part rotating the carrier part so that the inclination angle is reduced.

Furthermore, the micro LED display manufacturing device may further include: a flow generator generating a flow of the fluid toward the carrier substrate.

Furthermore, the micro LED display manufacturing device may further include: a laminating part laminating an upper portion of the carrier substrate with an upper film and laminating a lower portion of the carrier substrate with a lower film.

Furthermore, the carrier part may include: a carrier substrate having a seating recess in which each of the micro LEDs is seated, a non-seating region where no micro LEDs are seated, and a vacuum hole formed in a lower portion of the seating recess; and a support body detachably coupled to the carrier substrate to support the carrier substrate under the carrier substrate, and including a common chamber in communication with a plurality of vacuum holes.

Furthermore, the micro LED display manufacturing device may further include: an air pump that is in communication with the common chamber and sucks and discharges air inside the common chamber.

Furthermore, the micro LED display manufacturing device may further include: a vacuum pressure measuring device measuring pressure in the common chamber so that when it is determined that the pressure in the common chamber reaches a reference pressure, the carrier part is lifted.

Furthermore, the micro LED display manufacturing device may further include: the air pump provided at a first side of the common chamber to suck and discharge air in the common chamber; and a fluid pump provided at a second side of the common chamber to suck and discharge the fluid in the common chamber.

According to another aspect of the present disclosure, there is provided a method of manufacturing a micro LED display, the method including: holding micro LEDs of the same type inserted into a storage tank in which a fluid is stored onto a carrier substrate at positions spaced apart a predetermined pitch distance; and transferring the micro LEDs seated on the carrier substrate to a pixel substrate outside of the storage tank.

Furthermore, in the holding of micro LEDs of the same type, the micro LEDs inserted into the storage tank may be composed of only normal micro LEDs.

Furthermore, in the holding of micro LEDs of the same type, at least one of upper and lower surfaces of each of the micro LEDs may be treated to be hydrophobic or hydrophilic so that the micro LED may be maintained in a forward direction while floating on a fluid surface.

Furthermore, in the holding of micro LEDs of the same type, at least one of upper and lower surfaces of each of the micro LEDs may have a high density than the other one so that the micro LED may be maintained in a forward direction while floating on a fluid surface.

Furthermore, the holding of micro LEDs of the same type may include: testing whether each of the micro LEDs is seated in a seating recess of the carrier substrate.

Furthermore, in the holding of micro LEDs of the same type, the carrier substrate may be lifted while forming an inclination angle with the fluid.

Furthermore, the carrier substrate may repeat lifting and lowering operations at the same inclination angle.

Furthermore, the transferring of the micro LEDs may include: holding, by a transfer head, first micro LEDs of a first carrier substrate on which the first micro LEDs are seated and transferring the first micro LEDs to the pixel substrate; holding, by the transfer head, second micro LEDs of a second carrier substrate on which the second micro LEDs are seated and transferring the second micro LEDs to the pixel substrate; and holding, by the transfer head, third micro LEDs of a third carrier substrate on which the third micro LEDs are seated and transferring the third micro LEDs to the pixel substrate, wherein the first to third micro LEDs may constitute a pixel unit in the pixel substrate.

Furthermore, the method may further include:

laminating an upper portion of the carrier substrate with an upper film and laminating a lower portion of the carrier substrate with a lower film.

Furthermore, the carrier substrate may be made of a flexible material, wherein the method may further include: reeling the carrier substrate laminated with the upper and lower films onto a main reel.

According to still another aspect of the present disclosure, there is provided a method of manufacturing a micro LED display, the method including: removing an upper film of a pixel substrate laminated with the upper film and a lower film; disposing a circuit board on the pixel substrate; bonding micro LEDs of the pixel substrate to the circuit board; and removing the lower film of the pixel substrate.

According to still another aspect of the present disclosure, there is provided a method of manufacturing a micro LED display, the method including: inserting first micro LEDs fabricated and individualized on a first growth substrate into a first storage tank; holding the first micro LEDs inserted into the first storage tank onto a first carrier substrate; inserting second micro LEDs fabricated and individualized on a second growth substrate into a second storage tank; holding the second micro LEDs inserted into the second storage tank onto a second carrier substrate; inserting third micro LEDs fabricated and individualized on a third growth substrate into a third storage tank; holding the third micro LEDs inserted into the third storage tank onto a third carrier substrate; holding, by a transfer head, the first micro LEDs of the first carrier substrate on which the first micro LEDs are seated and transferring the first micro LEDs to a pixel substrate; holding, by the transfer head, the second micro LEDs of the second carrier substrate on which the second micro LEDs are seated and transferring the second micro LEDs to the pixel substrate; and holding, by the transfer head, the third micro LEDs of the third carrier substrate on which the third micro LEDs are seated and transferring the third micro LEDs to the pixel substrate, wherein the first to third micro LEDs may constitute a pixel unit in the pixel substrate.

### Advantageous Effects

As described above, in the micro LED display manufacturing device and the method of manufacturing the micro LED display according to the present disclosure, through a hybrid transfer process that combines the fluid transfer step and the head transfer step, it is possible to more efficiently perform a micro LED transfer process for manufacturing the micro LED display. In addition, in the micro LED transfer process, it is possible to prevent a factor (specifically, particles adhered to the surfaces of the micro LEDs) that may cause defects in the process of moving a substrate (e.g., the carrier substrate or the pixel substrate) to which the micro LEDs are transferred. As a result, it is possible to more effectively manufacture a micro LED display of good quality.

### DESCRIPTION OF DRAWINGS

FIG. 1 is a view illustrating micro LEDs to be transferred by a transfer head;

FIG. 2 is a view illustrating a micro LED structure transferred to and mounted on a circuit board or a pixel substrate by the transfer head;

FIG. 3 is a view schematically illustrating a method of manufacturing a micro LED display using a micro LED display manufacturing device according to the present disclosure;

FIG. 4 is a view schematically illustrating a fluid transfer step using a carrier part of the micro LED display manufacturing device according to the present disclosure;

FIG. 5 is a view schematically illustrating the carrier part as viewed from above;

FIGS. 6A to 8B are views illustrating various embodiments of pixel arrangement in a pixel substrate according to a pitch distance of seating recesses of a carrier substrate;

FIGS. 9, 10A, and 10B are views schematically illustrating various embodiments of a fluid transfer step using a carrier part of a micro LED display manufacturing device according to the present disclosure;

FIG. 11 is a view schematically illustrating a laminating part according to the present disclosure; and

FIGS. 12A, 12B, and 12C are views schematically illustrating a process of bonding micro LEDs of a laminated substrate to a circuit board.

### MODE FOR INVENTION

Contents of the description below merely exemplify the principle of the present disclosure. Therefore, those of ordinary skill in the art may implement the theory of the present disclosure and invent various apparatuses which are included within the concept and the scope of the present disclosure even though it is not clearly explained or illustrated in the description. Furthermore, in principle, all the conditional terms and embodiments listed in this description are intended for the purpose of understanding the concept of the present disclosure clearly, and one should understand that this invention is not limited the specifically-listed embodiments and the conditions.

The above described objectives, features, and advantages will be more apparent through the following detailed description related to the accompanying drawings, and thus those of ordinary skill in the art may easily implement the technical spirit of the present disclosure.

The embodiments of the present disclosure will be described with reference to cross-sectional views and/or perspective views which schematically illustrate ideal embodiments of the present disclosure. For explicit and convenient description of the technical content, sizes or thicknesses of films and regions and diameters of holes in the figures may be exaggerated. Therefore, variations from the shapes of the illustrations as a result, for example, of manufacturing techniques and/or tolerances, are to be expected. In addition, a limited number of micro LEDs are illustrated in the drawings. Thus, the embodiments should not be construed as limited to the particular shapes of regions illustrated herein but are to include deviations in shapes that result, for example, from manufacturing.

Wherever possible, the same reference numerals will be used throughout different embodiments and the description to refer to the same or like elements or parts. In addition, the configuration and operation already described in other embodiments will be omitted for convenience.

Hereinafter, exemplary embodiments of the present disclosure will be described in detail with reference to the accompanying drawings.

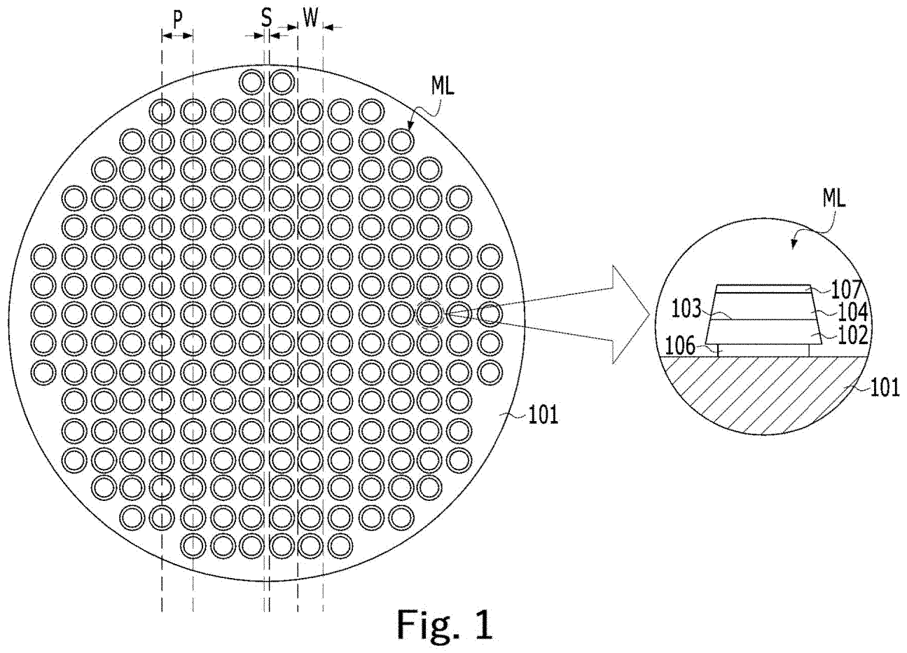

FIG. 1 is a view illustrating a plurality of micro LEDs ML to be transferred by a transfer head according to an embodiment of the present disclosure. The micro LEDs ML are fabricated and disposed on a growth substrate 101.

The growth substrate 101 may be embodied by a conductive substrate or an insulating substrate. For example, the growth substrate 101 may be made of at least one selected from among the group consisting of sapphire (Al₂O₃), SiC, Si, GaAs, GaN, ZnO, Si, GaP, InP, Ge, and Ga₂O₃.

Each of the micro LEDs ML may include: a first semiconductor layer 102; a second semiconductor layer 104; an active layer 103 provided between the first semiconductor layer 102 and the second semiconductor layer 104; a first contact electrode 106; and a second contact electrode 107.

The first semiconductor layer 102, the active layer 103, and the second semiconductor layer 104 may be formed by performing metalorganic chemical vapor deposition (MOCVD), chemical vapor deposition (CVD), plasma-enhanced chemical vapor deposition (PECVD), molecular-beam epitaxy (MBE), hydride vapor phase epitaxy (HVPE), or the like.

The first semiconductor layer 102 may be implemented, for example, as a p-type semiconductor layer. A p-type semiconductor layer may be made of a semiconductor material having a composition formula of InxAlyGa1-x-yN (0≤x≤1, 0≤y≤1, 0≤x+y≤1) selected from among, for example, GaN, AlN, AlGaN, InGaN, InN, InAlGaN, AlInN, and the like, and the layer may be doped with a p-type dopant such as Mg, Zn, Ca, Sr, or Ba.

The second semiconductor layer 104 may be implemented, for example, as an n-type semiconductor layer. The n-type semiconductor layer may be made of a semiconductor material having a composition formula of InxAlyGa1-x-yN (0≤x≤1, 0≤y≤1, 0≤x+y≤1) selected from among, for example, GaN, AlN, AlGaN, InGaN, InN, InAlGaN, AlInN, and the like, and the layer may be doped with an n-type dopant such as Si, Ge, or Sn.

However, the present disclosure is not limited to this. The first semiconductor layer 102 may be implemented as an n-type semiconductor layer, and the second semiconductor layer 104 may be implemented as a p-type semiconductor layer.

The active layer 103 is a region where electrons and holes are recombined. As the electrons and the holes are recombined, the active layer 103 transits to a low energy level and generates light having a wavelength corresponding thereto. The active layer 103 may be made of a semiconductor material having a composition formula of InxAlyGa1-x-yN (0≤x≤1, 0≤y≤1, 0≤x+y≤1) and may have a single quantum well structure or a multi quantum well (MQW) structure. In addition, the active layer 103 may have a quantum wire structure or a quantum dot structure.

The first contact electrode 106 may be provided on the first semiconductor layer 102, and the second contact electrode 107 may be provided on the second semiconductor layer 104. The first contact electrode 106 and/or the second contact electrode 107 may include at least one layer and may be made of various conductive materials including a metal, conductive oxide, and conductive polymer.

The plurality of micro LEDs ML formed on the growth substrate 101 are separated into individual pieces by cutting along a cutting line using a laser or the like or by etching. Then, it is possible to separate the individual micro LEDs ML from the growth substrate 101 by a laser lift-off (LLO) process.

In FIG. 1, the letter ‘P’ denotes a pitch distance between the micro LEDs ML, ‘S’ denotes a separation distance between the micro LEDs ML, and ‘W’ denotes a width of each micro LED ML. Although FIG. 1 illustrates that each cross-section of the micro LEDs is circular, a cross-section of the micro LEDs is not limited thereto. For example, the micro LED ML may have a cross-section shape other than the circular cross-section, such as a quadrangular cross-section, according to a method of fabricating the micro LEDs ML on the growth substrate 101.

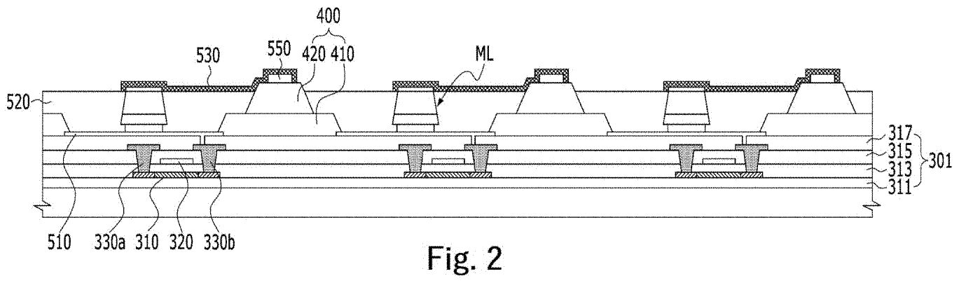

FIG. 2 is a view illustrating a micro LED structure formed by being transferred to and mounted on a circuit board by the transfer head according to the embodiment of the present disclosure. Here, the circuit board may be a substrate having a circuit part capable of driving micro LEDs ML transferred to a pixel substrate, and may be a substrate having a circuit part and bonded with micro LEDs of a pixel substrate without a circuit part by a bonding process.

The circuit board 301 may include various materials. For example, the circuit board 301 may be made of a transparent glass material having SiO₂ as a main component. However, materials of the circuit board 301 are not limited to this. For example, the circuit board 301 may be made of a transparent plastic material and have solubility. The plastic material may be an organic substance selected from among the group consisting of polyethersulfone (PES), polyacrylate (PAR), polyetherimide (PEI), polyethylene naphthalate (PEN), polyethylene terephthalate (PET), polyphenylene sulfide (PPS), polyallylate, polyimide, polycarbonate (PC), cellulose triacetate (TAC), and cellulose acetate propionate (CAP).

In the case of a bottom emission type in which an image is implemented in a direction of the circuit board 301, the circuit board 301 is required to be made of a transparent material. However, in the case of a top emission type in which an image is implemented in a direction opposite to the circuit board 301, the circuit board 301 is not required to be made of a transparent material. In this case, the circuit board 301 may be made of metal.

In the case of forming the circuit board 301 using metal, the circuit board 301 may be made of at least one metal selected from among the group consisting of iron, chromium, manganese, nickel, titanium, molybdenum, stainless steel (SUS), an Invar alloy, an Inconel alloy, and a Kovar alloy, but is not limited thereto.

The circuit board 301 may include a buffer layer 311. The buffer layer 311 may provide a flat surface and block foreign matter or moisture from penetrating through the circuit board 301. For example, the buffer layer 311 may include an inorganic substance such as silicon oxide, silicon nitride, silicon oxynitride, aluminum oxide, aluminum nitride, titanium oxide, and titanium nitride, or an organic substance such as polyimide, polyester, and acrylic. Alternatively, the buffer layer 311 may be formed into a stacked body including a plurality of the exemplified materials.

A thin-film transistor (TFT) may include an active layer 310, a gate electrode 320, a source electrode 330a, and a drain electrode 330b.

Hereinafter, a case where a TFT is a top gate type in which the active layer 310, the gate electrode 320, the source electrode 330a, and the drain electrode 330b are sequentially formed will be described. However, the present embodiment is not limited thereto, and various types of TFTs such as a bottom gate type may be employed.

The active layer 310 may include a semiconductor material, such as amorphous silicon or polycrystalline silicon. However, the present embodiment is not limited thereto, and the active layer 310 may include various materials. As an alternative embodiment, the active layer 310 may include an organic semiconductor material or the like.

As another alternative embodiment, the active layer 310 may include an oxide semiconductor material. For example, the active layer 310 may include an oxide of a metal element selected from Groups 12, 13, and 14 elements such as zinc (Zn), indium (In), gallium (Ga), tin (Sn), cadmium (Cd), and germanium (Ge), and a combination thereof.

A gate insulating layer 313 is formed on the active layer 310. The gate insulating layer 313 serves to electrically isolate the active layer 310 and the gate electrode 320. The gate insulating layer 313 may be formed into a multilayer or a single layer of a film made of an inorganic substance such as silicon oxide and/or silicon nitride.

The gate electrode 320 is provided on the gate insulating layer 313. The gate electrode 320 may be connected to a gate line (not illustrated) applying an on/off signal to the TFT.

The gate electrode 320 may be made of a low-resistivity metal. In consideration of adhesion with an adjacent layer, surface flatness of layers to be stacked, and processability, the gate electrode 320 may be formed into a multilayer or a single layer, which is made of at least one metal selected from among the group consisting of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

An interlayer insulating film 315 is provided on the gate electrode 320. The interlayer insulating film 315 electrically isolates the source electrode 330a, the drain electrode 330b, and the gate electrode 320. The interlayer insulating film 315 may be formed into a multilayer or single layer of a film made of an inorganic substance. For example, the inorganic substance may be a metal oxide or a metal nitride. Specifically, the inorganic substance may include silicon dioxide silicon nitride (SiNx), silicon oxynitride (SiON), aluminum oxide (Al₂O₃), titanium dioxide (TiO₂), tantalum pentoxide (Ta₂O₅), hafnium dioxide (HfO₂), or zirconium dioxide (ZrO₂).

The source electrode 330a and the drain electrode 330b are provided on the interlayer insulating film 315. The source electrode 330a and the drain electrode 330b may be formed into a multilayer or a single layer, which is made of at least one metal selected from among the group consisting of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). The source electrode 330a and the drain electrode 330b are electrically connected to a source region and a drain region of the active layer 310, respectively.

A planarization layer 317 is formed on the TFT. The planarization layer 317 is configured to cover the TFT, thereby eliminating a height difference caused by the TFT and planarizing the top surface. The planarization layer 317 may be formed into a single layer or a multilayer of a film made of an organic substance. The organic substance may include a general-purpose polymer such as polymethyl methacrylate (PMMA) and polystyrene (PS); a polymer derivative having a phenol group; an acryl-based polymer, an imide-based polymer, an arylether-based polymer, an amide-based polymer, a fluorine-based polymer, a p-xylene-based polymer, a vinyl alcohol-based polymer; and a blend thereof. In addition, the planarization layer 317 may be formed into a composite stacked body including an inorganic insulating layer and an organic insulating layer.

A first electrode 510 is provided on the planarization layer 317. The first electrode 510 may be electrically connected to the TFT. Specifically, the first electrode 510 may be electrically connected to the drain electrode 330b through a contact hole formed in the planarization layer 317. The first electrode 510 may have various shapes. For example, the first electrode 510 may be patterned in an island layout. A bank layer 400 defining a pixel region may be disposed on the planarization layer 317. The bank layer 400 may include a receiving recess where each of the micro LEDs 100 will be received. The bank layer 400 may include, for example, a first bank layer 410 defining the receiving recess. A height of the first bank layer 410 may be determined by a height and viewing angle of the micro LED ML. A size (width) of the receiving recess may be determined by resolution, pixel density, and the like, of a display device. In an embodiment, the height of the micro LED ML may be greater than that of the first bank layer 410. The receiving recess may have a quadrangular cross-section. However, the present disclosure is not limited thereto. For example, the receiving recess may have various cross-section shapes, such as polygonal, rectangular, circular, conical, elliptical, and triangular.

The bank layer 400 may further include a second bank layer 420 on the first bank layer 410. The first bank layer 410 and the second bank layer 420 have a height difference, and the second bank layer 420 may be smaller in width than the first bank layer 410. A conductive layer 550 may be disposed on the second bank layer 420. The conductive layer 550 may be disposed in a direction parallel to a data line or a scan line, and may be electrically connected to a second electrode 530. However, the present disclosure is not limited thereto. The second bank layer 420 may be omitted, and the conductive layer 550 may be disposed on the first bank layer 410. Alternatively, the second bank layer 420 and the conductive layer 500 may be omitted, and the second electrode 530 may be formed over the entire display substrate 301 such that the second electrode 530 serves as an electrode that pixels P share. The first bank layer 410 and the second bank layer 420 may include a material absorbing at least a part of light, a light reflective material, or a light scattering material. The first bank layer 410 and the second bank layer 420 may include an insulating material that is translucent or opaque to visible light (e.g., light in a wavelength range of 380 to 750 nm).

For example, the first bank layer 410 and the second bank layer 420 may be made of a thermoplastic such as polycarbonate (PC), polyethylene terephthalate (PET), polyethersulfone, polyvinyl butyral, polyphenylene ether, polyamide, polyetherimide, a norbornene system resin, a methacrylic resin, and a cyclic polyolefin system resin; a thermosetting plastic such as an epoxy resin, a phenolic resin, a urethane resin, an acrylic resin, a vinyl ester resin, an imide-based resin, an urethane-based resin, a urea resin, and melamine resin; or an organic insulating substance such as polystyrene, polyacrylonitrile, and polycarbonate, but are not limited thereto.

As another example, the first bank layer 410 and the second bank layer 420 may be made of an inorganic insulating substance such as inorganic oxide or inorganic nitride including SiOx, SiNx, SiNxOy, AlOx, TiOx, TaOx, or ZnOx, but are not limited thereto. In an embodiment, the first bank layer 410 and the second bank layer 420 may be made of an opaque material such as a black matrix material. The insulating black matrix material may include an organic resin; a resin or a paste including a glass paste and a black pigment; metal particles such as nickel, aluminum, molybdenum, and an alloy thereof; metal oxide particles (e.g., chromium oxide); metal nitride particles (e.g., chromium nitride); or the like. In a modification, the first bank layer 410 and the second bank layer 420 may be distributed Bragg reflectors (DBRs) having high reflectivity or mirror reflectors made of a metal.

The micro LED 100 is disposed in the receiving recess. The micro LED ML may be electrically connected to the first electrode 510 in the receiving recess.

The micro LEDs ML emit light having wavelengths of different colors such as red, green, blue, white, and the like. With the micro LEDs ML, it is possible to realize white light by using a fluorescent material or by combining colored lights. The micro LEDs 100 may be picked up from the growth substrate 101 individually or collectively by the transfer head 15 according to the embodiment of the present disclosure, transferred to the circuit board 301, and received in the respective recesses of the display substrate 301.

The micro LED ML includes a p-n diode, the first contact electrode 106 disposed on one side of the p-n diode, and the second contact electrode 107 disposed on the opposite side of the first contact electrode 106. The first contact electrode 106 may be connected to the first electrode 510, and the second contact electrode 107 may be connected to the second electrode 530.

The first electrode 510 may include: a reflective layer made of Ag, Mg, Al, Pt, Pd, Au, Ni, Nd, Ir, Cr, or a compound thereof; and a transparent or translucent electrode layer provided on the reflective layer. The transparent or translucent electrode layer may include at least one selected from among the group consisting of indium tin oxide (ITO), indium zinc oxide (IZO), zinc oxide (ZnO), indium oxide (In₂O₃), indium gallium oxide (IGO), and aluminum zinc oxide (AZO).

A passivation layer 520 surrounds the micro LED ML in the receiving recess. The passivation layer 520 covers the receiving recess and the first electrode 510 by filling a space between the bank layer 400 and the micro LED ML. The passivation layer 520 may be made of an organic insulating substance. For example, the passivation layer 520 may be made of acrylic, poly (methyl methacrylate) (PMMA), benzocyclobutene (BCB), polyimide, acrylate, epoxy, polyester, or the like, but is not limited thereto.

The passivation layer 520 is formed to have a height not covering an upper portion of the micro LED ML, e.g., the second contact electrode 107, such that the second contact electrode 107 is exposed by the passivation layer 520. The second electrode 530 may be formed on the passivation layer 520 electrically connected to the exposed second contact electrode 107 of the micro LED ML.

The second electrode 530 may be disposed on the micro LED ML and the passivation layer 520. The second electrode 530 may be made of a transparent conductive material such as ITO, IZO, ZnO, In₂O₃, or the like.

Although the vertical-type micro LED ML in which the first contact electrode 106 and the second contact electrode 107 are provided on upper and lower surfaces thereof has been described, the prevent invention is not limited thereto. For example, the micro LED ML may be a lateral-type or flip-type micro LED ML in which both the first contact electrode 106 and the second contact electrode 107 are provided on any one of the upper and lower surfaces thereof. In this case, the first electrode 510 and the second electrode 530 may also be provided at appropriate positions.

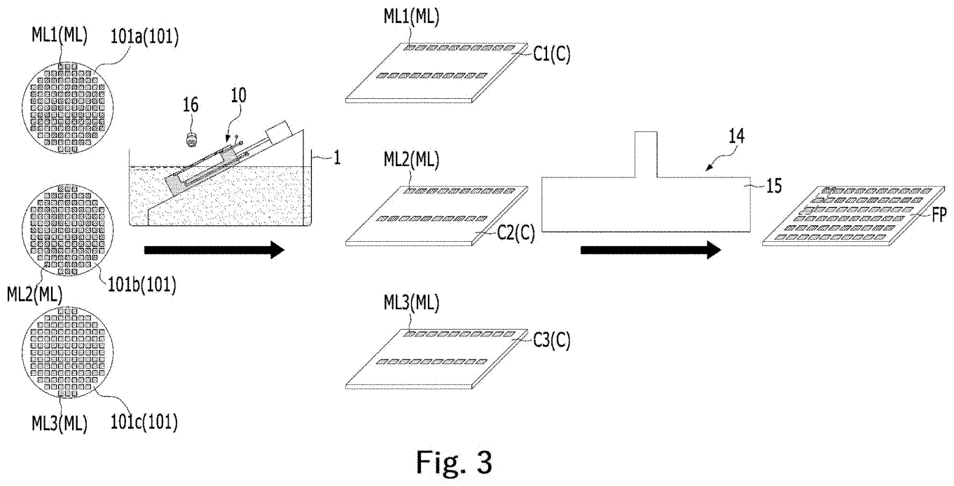

FIG. 3 is a view schematically illustrating a micro LED display manufacturing method using a micro LED display manufacturing device according to the present disclosure.

As illustrated in FIG. 3, the micro LED display manufacturing device according to the present disclosure may include a carrier part 10 for performing a fluid transfer process and a transfer head part 14 for performing a head transfer process. In the present disclosure, using the micro LED display manufacturing device, a fluid transfer step of holding micro LEDs ML of the same type inserted into a storage tank 1 in which a fluid is stored onto a carrier substrate C at positions spaced apart a predetermined pitch distance, and a head transfer step of transferring the micro LEDs ML on the carrier substrate C to a pixel substrate FP outside the storage tank 1 may be performed to manufacture a micro LED display.

The carrier part 10 according to the present disclosure may perform the fluid transfer step by providing the carrier substrate C onto which the micro LEDs ML of the same type inserted into the storage tank 1 in which the fluid is stored are held at positions spaced apart a predetermined pitch distance, and the transfer head part 14 may perform the head transfer step of transferring the micro LEDs ML on the carrier substrate C to the pixel substrate FP outside the storage tank 1. Here, the fluid stored in the storage tank 1 may be in a liquid form.

In the present disclosure, after the fluid transfer step of transferring the micro LEDs ML fabricated on the growth substrate 101 to the carrier substrate C using the carrier part 10, and then the head transfer step of transferring the micro LEDs ML to the pixel substrate FP using the transfer head part 14 may be performed. When the pixel substrate FP is provided with a circuit part, the pixel substrate FP may function as a circuit board 301. The pixel substrate FP may function as the circuit board 301 when having the circuit part, and thus may be the same as the circuit board 301. Therefore, the micro LEDs ML of the carrier substrate C may be transferred to the circuit board 301 by the head transfer step.

A plurality of micro LEDs ML fabricated on the growth substrate 101 may have non-uniform light emission characteristics within a micro LED existing region in which the micro LEDs ML on the growth substrate 101 exist. As an example, a micro LED ML located at a first end of the growth substrate 101 and a micro LED ML located at a second end of the growth substrate 101 may differ in light emission characteristics. In this case, when the micro LEDs ML of the growth substrate 101 are transferred to the pixel substrate FP using a head transfer method, the non-uniform light emission characteristics of the micro LEDs ML may be maintained on the pixel substrate FP. This is because, since the head transfer method is a method in which a head holds micro LEDs ML in at least a partial region of the growth substrate 101 and transfers the micro LEDs to the pixel substrate FP, the micro LEDs ML are transferred while their light emission characteristics are maintained. Therefore, it may be appropriate to use a fluid transfer method as a method of transferring the micro LEDs ML of the growth substrate 101 to the carrier substrate C before transferring the micro LEDs ML to the pixel substrate FP.

Meanwhile, a warpage phenomenon due to thermal deformation may occur in the growth substrate 101. In this case, since flatness of the growth substrate 101 is relatively low, there may be a high probability that the micro LEDs ML are damaged during a micro LED ML holding process.

The above disadvantage may be a problem that occurs before transferring the micro LEDs ML fabricated on the growth substrate 101 to a next substrate (e.g., the carrier substrate C or a temporary substrate). In other words, this may be a problem that has already occurred in the growth substrate 101.

In the present disclosure, by using the fluid transfer method as a method of transferring the micro LEDs ML of the growth substrate 101 to the next substrate (e.g., the carrier substrate C or the temporary substrate) before transferring the micro LEDs ML to the pixel substrate FP, a transfer process may be performed by supplementing the problem occurring in the growth substrate 101.

The fluid transfer method is a method of transferring the micro LEDs ML to the carrier substrate C using a fluid, so that the light emission characteristics of the micro LEDs ML transferred from the growth substrate 101 to the carrier substrate C may become uniform. Specifically, the fluid transfer method is a method of inserting the micro LEDs ML of the growth substrate 101 into the storage tank 1 in which the fluid is stored, and then transferring the inserted micro LEDs ML to the carrier substrate C using the fluid. Therefore, the micro LEDs ML on the growth substrate 101 are randomly arranged on the fluid surface, so that the light emission characteristics become uniform.

In addition, since the fluid transfer method is not a method of holding the micro LEDs ML on the growth substrate 101 to transfer the micro LEDs ML to the carrier substrate C, the micro LEDs ML may be transferred to the carrier substrate C without being negatively influenced by the warpage phenomenon of the growth substrate 101. This may prevent damage to the micro LEDs ML.

As illustrated in FIG. 3, in the present disclosure, the micro LED ML of the growth substrate 101 may be transferred to the carrier substrate C by the fluid transfer method using the carrier part 10. This process may be performed in the fluid transfer step. The micro LEDs ML transferred to the carrier substrate C by a fluid transfer process may have a pitch distance determined according to the pitch distance of seating recesses 11a of the carrier substrate C. In the present disclosure, as an example, as illustrated in FIG. 3, the seating recesses 11a of the carrier substrate C are formed with a three-fold pitch distance of a y-direction pitch distance of the micro LEDs ML of the growth substrate 101. Therefore, first to third micro LEDs ML1, ML2, and ML3 transferred to the carrier substrate C may be arranged on respective carrier substrates C at a three-fold pitch distance in the y-direction. Here, the first micro LEDs ML1 may be red micro LEDs that emit red light, the second micro LEDs ML2 may be green micro LEDs that emit green light, and the third micro LEDs ML3 may be blue micro LEDs that emit blue light. The first to third micro LEDs ML1, ML2, and ML3 which will be described below may also be illustrated in the same configuration as the above-described configuration.

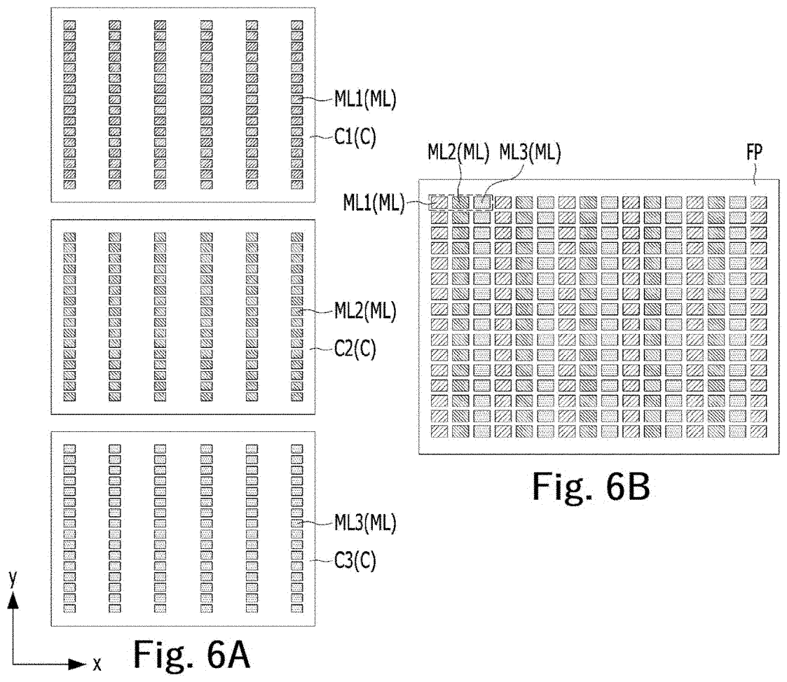

The micro LEDs ML transferred to the carrier substrate C may be transferred to the pixel substrate FP by the head transfer method using the transfer head part 14. In this case, the pixel arrangement in the pixel substrate FP may be formed differently according to the pitch distance of the seating recesses 11a of the carrier substrate C. In FIG. 3, as an example, since the seating recesses 11a are formed at a three-fold pitch distance of the y-direction pitch distance of the micro LEDs ML of the growth substrate 101, an arrangement in which micro LEDs ML of the same type are transferred to the pixel substrate FP in the x-direction. A detailed description thereof will be given later in the description with reference to FIGS. 6A to 8B.

Since the present disclosure uses the fluid transfer method as a method of transferring the micro LEDs ML of the growth substrate 101 to the carrier substrate C, the micro LEDs ML may be transferred to the carrier substrate C in a state in which a problem that may occur in the growth substrate 101 is supplemented.

Then, the micro LEDs ML transferred to the carrier substrate C may be rapidly transferred to the pixel substrate FP using the transfer head part 14. In the case of the head transfer method, since the micro LEDs ML are collectively held and simultaneously transferred to the pixel substrate FP, this may be effective in terms of a rapid transfer process.

The transfer head part 14 for performing the head transfer method may be a transfer head that uses electrostatic force, electromagnetic force, magnetic force, vacuum suction force, Van der Waals force, or bonding force that can be lost due to heat or light as a holding force for holding the micro LEDs ML. The holding force used by the transfer head part 14 is not limited thereto. In addition, the transfer head part 14 may have a structure suitable for the holding force for holding the micro LEDs ML to transfer the micro LEDs ML of the carrier substrate C to the pixel substrate FP. In the present disclosure, as an example, the transfer head part 14 is provided with a transfer head 15 to perform the head transfer step.

In the present disclosure, by providing the transfer head part 14 as described above, the advantages of the head transfer method may be used in a micro LED transfer process.

As described above, the present disclosure may implement a hybrid transfer process by simultaneously using the fluid transfer method and the head transfer method in the transfer process of transferring the micro LEDs ML from the growth substrate 101 to the pixel substrate FP in order to manufacture the micro LED display device.

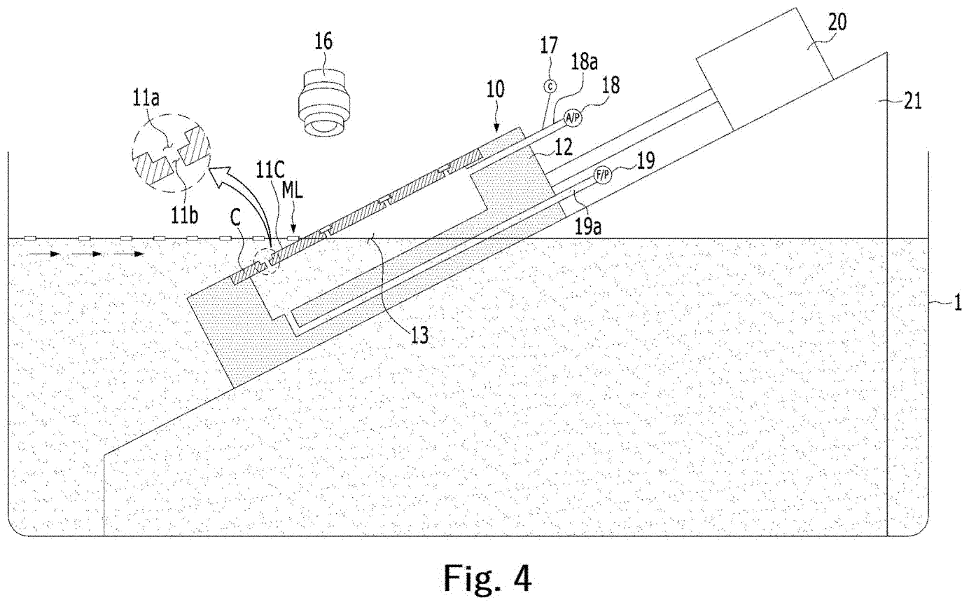

FIG. 4 is a view schematically illustrating a fluid transfer step using the carrier part 10 according to the present disclosure.

As illustrated in FIG. 4, the micro LEDs ML of the growth substrate 101 may be inserted into the storage tank 1. In this case, the micro LEDs ML of the growth substrate 101 may be inserted into the storage tank 1 in which the fluid is stored by an LLO process. In the fluid transfer step, the micro LEDs ML inserted into the storage tank 1 may be composed of only normal micro LEDs. This may be possible by selectively detaching only normal micro LEDs except for defective micro LEDs when performing the LLO process on the growth substrate 101. By the process of inserting only normal micro LEDs into the storage tank 1 through the LLO process, the problem in which the defective micro LEDs are transferred to the carrier substrate C may be prevented. In addition, there is an effect that a repair process of replacing a defective micro LED of the carrier substrate C with a normal micro LED may be omitted.

In the fluid transfer step, the micro LEDs ML inserted into the storage tank 1 may be implemented to float on the fluid surface through specific gravity control. In addition, in the fluid transfer step, at least one of upper and lower surfaces of each of the micro LEDs ML may be treated to be hydrophobic or hydrophilic so that the micro LED ML may be maintained in the forward direction while floating on the fluid surface because. One surface of the micro LED ML may be treated to be hydrophobic or hydrophilic depending on the characteristics of the fluid. Specifically, when the fluid in the storage tank 1 is hydrophobic, the surface of the micro LED ML may treated to be hydrophilic, and when the fluid in the storage tank 1 is hydrophilic, the surface of the micro LED ML may be treated to be hydrophobic. In other words, the surface of the micro LED ML may be treated to be imparted with a characteristic opposite to that of the fluid in the storage tank 1. This may enable the micro LED ML to be maintained in the forward direction without overturning. Here, the forward direction of the micro LED ML may be determined according to the position of a terminal of the micro LED ML.

In addition, in the fluid transfer step, at least one of the upper and lower surfaces of each of the micro LEDs ML may have a high density than the other one so that the micro LED ML may be maintained in the forward direction while floating on the fluid surface.

As such, through specific gravity control, hydrophobic or hydrophilic treatment on one surface, and density difference between one surface and the other surface, the micro LED ML may be maintained in the forward direction while floating on the fluid surface. This may prevent a transfer error problem in which an overturned micro LED ML is transferred to the carrier substrate C.

In the present disclosure, the fluid transfer process of transferring the micro LEDs ML inserted into the storage tank 1 to the carrier substrate C may be performed using the carrier part 10.

As illustrated in FIG. 4, the carrier part 10 may include the carrier substrate C and a support body 12 that is detachably coupled to the carrier substrate C to support the carrier substrate C.

The support body 12 may have a structure capable of supporting the carrier substrate C on an upper surface thereof, while having a shape stepped inside. Thus, a structure in which opposite ends of the carrier substrate C are supported and an outside thereof is protected by the support body 12 may be formed. In this case, the structure of the carrier part 10 including the carrier substrate C and the support body 12 is illustrated as an example and thus is not limited thereto, and the structure in which the support body 12 supports the carrier substrate C is also not limited thereto.

A common chamber 13 may be provided between an inner surface of the support body 12 and the carrier substrate C. Such a structure may have a form in which the common chamber 13 is provided inside the carrier part 10. The common chamber 13 may be provided inside the carrier part 10 at a position under the carrier substrate C. An air pump 18 that is in communication with the common chamber 13 and sucks and discharges air inside the common chamber 13 may be coupled to the common chamber 13.

The air pump 18 may function to generate a vacuum pressure in a vacuum hole 11b. Therefore, the air pump 18 may be provided at a first side of the common chamber 13 to suck and discharge air inside the common chamber 13. Preferably, the air pump 18 is provided at the first side of the common chamber 13 at a position corresponding to one of opposite ends of the carrier part 10, the end first escaping out of the fluid by a lifting process of the carrier part 10. This may be to efficiently generate a vacuum pressure in the vacuum hole 11b positioned outside the fluid without interference of the fluid flowing into the common chamber 13. In this case, the air pump 18 may be provided at the first side of the common chamber 13 by an air pump pipe 18a allowing communication between the air pump 18 and the common chamber 13. The air pump 18 may be configured to be coupled to the carrier part 10 to be moved in conjunction with the carrier part 10 during a reciprocating motion of the carrier part 10. The air pump 18 may be provided in a fixed form on an outside of the storage tank 1, and may be configured to be coupled to the carrier part 10 by an elastic pipe so that the pipe may expand and contract during the reciprocating motion of the carrier part 10. However, a problem wherein the fluid is vibrated by the pipe that expands and contracts may occur, which negatively influence the movement of the micro LEDs ML along the flow direction of the fluid. Therefore, preferably, the air pump 18 is configured to be fixedly coupled to the carrier part 10 to be reciprocated in conjunction with the reciprocating motion of the carrier part 10.

The carrier substrate C of the carrier part 10 may be configured to be lifted while forming an inclination angle with the fluid of the storage tank 1. Specifically, the carrier substrate C may be lifted while an upper surface thereof forms the inclination angle with the fluid.

In order to implement such a structure, the present disclosure may include a driving part 20. The driving part 20 may lift the carrier part 10 while maintaining a constant inclination angle. Thus, the carrier substrate C provided on the carrier part 10 may be lifted while forming the inclination angle with the fluid. The driving part 20 may rotate the carrier part 10 so that the inclination angle may be reduced. Specifically, the driving part 20 may rotate the carrier part 10 so that the carrier part 10 and the fluid are level with each other. Thus, the inclination angle of the carrier part 10 may be reduced. This process may be performed after the process of fluidly transferring the micro LEDs ML to the carrier substrate C is completed. By rotating the carrier part 10 by the driving part 20 to allow the carrier substrate C to be level with the fluid, the head transfer process in which the micro LEDs ML transferred to the carrier substrate C are held and transferred to the pixel substrate FP may be performed more efficiently. The driving part 20 may be configured as a hydraulic cylinder or a motor as an example. The configuration of the driving part 20 is not limited thereto, and may be configured as a suitable means for driving the carrier part 10.

With the above configuration, the micro LEDs ML floating on the fluid surface may be transferred to the carrier substrate C.

The carrier substrate C may include a seating recess 11a in which each of the micro LEDs ML is seated, a non-seating region 11c where the micro LEDs ML are not seated, and the vacuum hole 11b formed a lower portion of the seating recess 11a. With this configuration of the carrier substrate C, the carrier part 10 according to the present disclosure may be composed of: the carrier substrate C including the seating recess 11a in which each of the micro LEDs ML is seated, the non-seating region 11c where no micro LEDs ML are seated, and the vacuum hole 11b formed in the lower portion of the seating recess 11a; and the support body 12 detachably coupled to the carrier substrate C to support the carrier substrate C under the carrier substrate C, and including the common chamber 13 in communication with a plurality of vacuum holes 11b.

The seating recess 11a may have an area capable of receiving the micro LED ML, and the area thereof may be larger than the horizontal area of the surface of the micro LED ML. The vacuum hole 11b may be formed in the lower portion of the seating recess 11a to be in communication with the seating recess 11a.

The vacuum hole lib may function to generate a vacuum pressure that allows the micro LED ML seated in the seating recess 11a to be held on the carrier substrate C. The vacuum pressure may be generated by the air pump 18 that is coupled to the common chamber 13 to be in communication therewith. Since the vacuum hole 11b is in communication with the common chamber 13 and the air pump 18 is provided in communication with the common chamber 13, as the air pump 18 may suck and discharge the air in the common chamber 13, the vacuum pressure may be generated or released in the vacuum hole 11b.

A case where vacuum pressure is generated in the vacuum hole 11b may be a case where as the carrier substrate C is lifted while forming the inclination angle with the fluid, the vacuum hole 11b is positioned outside the fluid. In this case, even when at least a part of the plurality of vacuum holes 11b formed in the carrier substrate C are positioned outside the fluid, the air pump 18 may be operated. In other words, the air pump 18 may selectively generate a vacuum pressure only in the vacuum holes 11b positioned outside the fluid.

In FIG. 4, as an example, a state in which as the carrier substrate C is lifted while forming an inclination angle with the fluid, three of four vacuum holes 11b provided in the carrier substrate C are positioned outside the fluid is illustrated. This may be a state in which micro LEDs ML moved along the flow direction of the fluid are seated in three seating recesses 11a in communication with the vacuum holes 11b positioned outside the fluid. In this case, the air pump 18 may be operated to generate a vacuum pressure in the vacuum holes 11b in communication with the seating recesses 11a in which the micro LEDs ML are seated. The micro LEDs ML seated in the seating recesses 11a may not be separated from the seating recesses 11a by a vacuum holding force formed in the vacuum holes 11b. Therefore, even when the carrier substrate C is lifted in order to allow a micro LED ML in a seating recess 11a in which no micro LED ML is seated, the micro LEDs ML first seated in the seating recesses 11a may be maintained held by the vacuum holding force without being separated therefrom.

Meanwhile, the vacuum hole 11b may function to create a flow for more effectively introducing the micro LED ML into the seating recess 11a. This may be implemented by a fluid pump 19 that sucks and discharges the fluid flowing into the common chamber 13 through the seating recess 11a and the vacuum hole 11b when the vacuum hole 11b is located inside the fluid. The fluid pump 19 may be provided at a second side of the common chamber 13. In other words, the fluid pump 19 may be provided at the second side of the common chamber 13 to suck and discharge the fluid in the common chamber 13.

The fluid pump 19 may be in communication with the common chamber 13 through a fluid pump pipe 19a. Therefore, preferably, the fluid pump pipe 19a is provided at the second side of the common chamber 13 at a position in the vicinity of where a large amount of fluid flowing into the common chamber 13 stays due to the inclination angle of the carrier part 10, so that the fluid in the common chamber 13 may be sucked and discharged by the operation of the fluid pump 19.

Thus, as the fluid flowing into the common chamber 13 through the seating recess 11a and the vacuum hole 11b is sucked, a flow of the fluid may be generated in the direction toward the seating recess 11a. As a result, a process for seating the micro LED ML into the seating recess 11a along the fluid flow formed toward the seating recess 11a by the fluid pump 19 may be performed more effectively.

In the present disclosure, through the provision of the air pump 18 provided at the first side of the common chamber 13 to suck and discharge the air in the common chamber 13 and the fluid pump 19 provided at the second side of the common chamber 13 to suck and discharge the fluid in the common chamber 13, each of the air pump 18 and the fluid pump 19 may be operated appropriately according to the inclination angle of the carrier substrate C. Thus, a micro LED transfer efficiency for transferring the micro LEDs ML to the carrier substrate C may be improved.

As illustrated in FIG. 4, the carrier substrate C is lifted while forming the inclination angle with the fluid, and the micro LEDs ML may be moved toward the seating recesses 11a of the carrier substrate C along the flow direction of the fluid. The arrow illustrated in FIG. 4 indicates the flow direction of the fluid. The flow direction of the fluid may be determined by a suitable means for forming the flow direction of the fluid, and a suitable structure may be provided. The flow direction of the fluid may be such that the flow of the fluid is generated behind (in the drawing of FIG. 4) the micro LEDs ML to allow the micro LEDs ML to be moved forward.

The micro LEDs ML may be moved on the fluid surface along the flow direction of the fluid, and the carrier substrate C may be lifted while forming the inclination angle with the fluid, so that the micro LEDs ML may be seated in the seating recesses 11a. When the seating recesses 11a in which the micro LEDs ML are seated and the vacuum holes 11b in communication therewith are positioned outside the fluid, the micro LEDs ML may be held and fixed in the vacuum holes 11b by vacuum force.

The non-seating region 11c may be formed on the carrier substrate C. The non-seating region 11c may be formed in the vicinity of the seating recesses 11a by not forming the seating recesses 11a. When the fluid is hydrophilic, a hydrophobic layer may be formed on the surface of the non-seating region 11c, and when the fluid is hydrophobic, a hydrophilic layer may be formed thereon. Thus, when moved along the flow direction of the fluid and brought into contact with the non-seating region 11c, the micro LEDs ML may easily slide down without being attached to the non-seating region 11c.

As illustrated in FIG. 4, the micro LEDs ML floating on the fluid surface along the flow direction in the fluid transfer step may be moved toward the carrier substrate C, and the carrier substrate C may be lifted while forming the inclination angle with the fluid. In this state, a micro LEDs ML closest to the carrier substrate C may be seated in a seating recess 11a of the carrier substrate C or may be brought into contact with the non-seating region 11c of the carrier substrate C. In FIG. 4, a state in which the micro LED ML closest to the carrier substrate C among the micro LEDs ML floating on the fluid surface is in contact with the non-seating region 11c. In this case, according to the hydrophobic or hydrophilic properties of the fluid stored in the storage tank 1, a layer having a property opposite to the surface of the non-seating region 11c may be formed. Thus, the micro LED ML in contact with the non-seating region 11c may slide without being attached to the non-seating region 11c.

The carrier substrate C may continue to be lifted while forming the inclination angle with the fluid. As the carrier substrate C is lifted, the micro LED ML in contact with the non-seating region 11c may be introduced into the seating recess 11a.

In the fluid transfer step, the carrier substrate C may repeat lifting and lowering operations at the same inclination angle. This may be a process for transferring the micro LEDs ML to the carrier substrate C by properly seating the micro LEDs ML in the seating recesses 11a. The lifting and lowering operations of the carrier substrate C may be repeatedly performed until the micro LEDs ML are seated in the corresponding seating recesses 11a.

The micro LEDs ML transferred to the carrier substrate C during the fluid transfer process may be introduced into the seating recesses 11a while floating on the fluid surface along the flow direction of the fluid. In this case, a problem wherein the micro LEDs ML are not properly seated in the seating recesses 11a may occur. In order to prevent this problem, in the present disclosure, a testing step of testing whether the micro LEDs ML are seated in the seating recesses 11a of the carrier substrate C may be performed. In order to perform the testing step, the present disclosure may include a vision tester 16 functioning to check whether the micro LEDs ML are properly seated in the seating recesses 11a.

As illustrated in FIG. 4, the vision tester 16 may be provided above the carrier part 10. The vision tester 16 may be provided at a spaced distance above the carrier part 10 at a position capable of checking the positions where the micro LEDs ML floating on the fluid surface in the storage tank 1 are first seated in the seating recesses 11a. In other words, the vision tester 16 may be provided above the positions where the micro LEDs ML are first seated in the seating recesses 11a due to the inclination angle as the carrier substrate C begins to form the inclination angle with the fluid. Through the vision tester 16 provided in such a structure, testing whether the micro LEDs ML are seated in the seating recesses 11a may be possible. In the present disclosure, by the process of checking whether the micro LEDs ML are properly seated using the vision tester 16, when the micro LEDs ML are not properly seated in the seating recesses 11a, the position of the carrier substrate C may be readjusted (specifically, lowered toward the fluid) so that the micro LEDs ML may be properly seated in the seating recesses 11a. As a result, transfer of the micro LEDs ML to the carrier substrate C may be completed without occurrence of any seating recesses 11a in which no micro LED ML is seated.

The present disclosure may include a vacuum pressure measuring device 17 for checking whether the micro LEDs ML are normally seated and held in the seating recesses 11a.

The vacuum pressure measuring device 17 may function to measure the pressure in the common chamber 13. In the present disclosure, when it is determined that the pressure in the common chamber 13 reaches a reference pressure by measuring the pressure in the common chamber 13 through the vacuum pressure measuring device 17, the carrier part 10 may be lifted through the driving part 20. In the present disclosure, when the pressure of the common chamber 13 reaches the reference pressure, the micro LEDs ML may be determined to be normally seated in the seating recesses 11a, and the driving part 20 may be controlled to lift the carrier part 10. A vacuum pressure may be generated in the vacuum holes 11b through the common chamber 13. Therefore, in the present disclosure, when it is checked through the vacuum pressure measuring device 17 that the pressure in the common chamber 13 reaches the reference pressure, it may be determined that the vacuum pressure is normally generated in all the vacuum holes 11b of the carrier substrate C, and the carrier part 10 may be lifted through the driving part 20. The vacuum pressure measuring device 17 may be provided in the form of a pressure gauge, but is not limited thereto, and may be provided as a suitable means for measuring pressure.

As described above, the present disclosure may include a means (e.g., the vision tester 16 and the vacuum pressure measuring device 17) for checking whether the micro LEDs ML are normally seated on the carrier substrate C. Thus, the fluid transfer process may be performed without occurrence of any micro LEDs ML missing from the carrier substrate C. As a result, reliability of the fluid transfer process may be increased.

As illustrate in FIG. 4, a sliding part 21 may be provided under the carrier part 10. The sliding part 21 may support a lower portion of the carrier part 10 on an upper surface thereof. The sliding part 21 may support the lower portion of the carrier part 10 as the lower portion of the carrier part 10 slides therealong. Therefore, the sliding part 21 may be formed in a suitable structure for allowing the sliding of the lower portion of the carrier part 10.

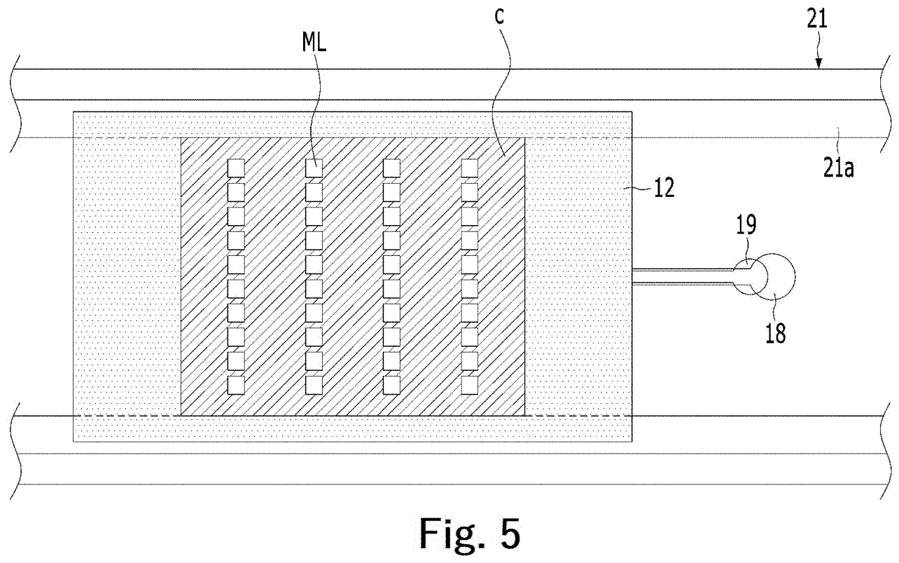

The sliding part 21 may have a structure in which the carrier part 10 is lifted while maintaining a constant inclination angle. With this structure, the upper surface of the sliding part 21 supporting the carrier part 10 may be formed as an inclined surface. The sliding part 21 may have a flat inclined surface, or may have a stepped portion 21a formed at each of opposite spaced supports so that the carrier part 10 may be supported by the respective stepped portions 21a. In the present disclosure, as an example, the stepped portions 21a is illustrated and described as being formed on the upper surface of the sliding part 21. This will be described in detail with reference to FIG. 5.

FIG. 5 is a view schematically illustrating a state in which the sliding part 21 supports the carrier part 10 on the upper surface thereof as viewed from above. In FIG. 5, the vacuum pressure measuring device 17 is omitted.

As illustrated in FIG. 5, the sliding part 21 may be composed of a first sliding part 21 and a second sliding part 21 having the stepped portions 21a formed on upper surfaces thereof. Since the sliding part 21 is provided so that at least a part thereof is immersed in the fluid, the sliding part 21 is required to have a structure that does not interfere with the flow of the fluid in the storage tank 1. In the present disclosure, the sliding part 21 may be composed of the first and second sliding parts 21, and the first and second sliding parts 21 may be provided spaced apart from each other inside the storage tank 1. The first and second sliding parts 21 may be provided at a spaced distance from each other so as to define a width greater than the vertical width (in the drawing of FIG. 5) of the carrier part 10. The first and second sliding parts 21 may be provided at a spaced distance from each other to have a margin width enough not to interfere with the reciprocating motion of the carrier part 10 that is lifted and lowered, while supporting at least partially respective upper and lower portions (in the drawing of FIG. 5) of the carrier part 10. Thus, the degree of interference with the flow of the fluid due to the sliding part 21 in the storage tank 1 may be minimized.

The first and second sliding parts 21 may support the carrier part 10 by the stepped portions 21a formed on the upper surfaces thereof, respectively. Therefore, the carrier part 10 may slide while at least a part of the lower portion thereof is supported by the stepped portions 21a of the first and second sliding parts 21.

The sliding part 21 described with reference to FIG. 5 is illustrated as an example, and thus the structure of the sliding part 21 is not limited thereto.

The present disclosure may include a dryer for drying the surface of the carrier part 10. The dryer may perform the drying after the carrier part 10 performs the fluid transfer process to complete the transfer of the micro LEDs ML to the carrier substrate C. The dryer may be provided as an air blower or heating means. The dryer is not limited thereto, and may be provided as a suitable means for drying the micro LEDs ML. In the present disclosure, through the provision of the dryer, a negative problem (e.g., malfunction of a circuit part due to the fluid) that may occur due to the fluid remaining on the surfaces of the micro LEDs ML during the fluid transfer process may be prevented.

Meanwhile, in the present disclosure, the fluid transfer process may be performed by moving the carrier part 10 to be lifted and lowered, or the level of the fluid provided in the storage tank 1 may be adjusted so that the micro LEDs ML may be seated in the seating recesses 11a of the carrier substrate C. Therefore, in the present disclosure, the fluid transfer process may be performed using a mechanism in which the carrier part 10 and the fluid are moved relative to each other.

After the fluid transfer step is completed, the head transfer step using the transfer head part 14 may be performed. In the head transfer step, the micro LEDs ML of the carrier substrate C may be transferred to the pixel substrate FP.

The transfer head part 14 may collectively hold the micro LEDs ML seated in the seating recesses 11a of the carrier substrate C and transfer the same to the pixel substrate FP. Therefore, an arrangement of the micro LEDs ML transferred from the pixel substrate FP may be formed according to the pitch distance of the seating recesses 11a.

FIGS. 6A to 8B are views illustrating various embodiments of pixel arrangement in a pixel substrate FP according to the pitch distance of seating recesses 11a of a carrier substrate C. The pixel substrate FP may include a seating recess 11a in which each of the micro LEDs ML transferred from the carrier substrate C is seated, and a vacuum hole 11b in which a vacuum pressure to vacuum-hold the micro LED ML seated in the seating recess 11a is generated.

FIG. 6A is a view illustrating micro LEDs ML transferred by the fluid transfer step to a carrier substrate C in which seating recesses 11a are formed at a three-fold pitch distance of an x-direction pitch distance of the micro LEDs ML of the growth substrate 101. As illustrated in FIGS. 6A and 6B, the carrier substrate C may include a first carrier substrate C1 to which first micro LEDs ML1 are transferred, a second carrier substrate C2 to which second micro LEDs ML2 are transferred, and a third carrier substrate C3 to which third micro LEDs ML3 are transferred.

The head transfer step may include a first head transfer step of holding, by the transfer head 15, the first micro LEDs ML1 of the first carrier substrate C1 on which the first micro LEDs ML1 are seated and transferring the same to a pixel substrate FP, a second head transfer step of holding, by the transfer head 15, the second micro LEDs ML2 of the second carrier substrate C2 on which the second micro LEDs ML2 are seated and transferring the same to the pixel substrate FP, and a third head transfer step of holding, by the transfer head 15, the third micro LEDs ML3 of the third carrier substrate C3 on which the third micro LEDs ML3 are seated and transferring the same to the pixel substrate FP, so that the first to third micro LEDs ML1, ML2, and ML3 may constitute a pixel unit in the pixel substrate FP.

This will be described in detail with reference to FIGS. 6A and 6B.

As illustrated in FIG. 6A, the respective micro LEDs ML1, ML2, and ML3 may be transferred to the carrier substrate C by the fluid transfer step. In this case, since the seating recesses 11a of the carrier substrate C are formed at a three-fold pitch distance of the x-direction pitch distance of the micro LEDs ML of the growth substrate 101, the micro LEDs ML on the carrier substrate C may be arranged at a three-fold pitch distance in the x-direction. In each of the carrier substrates C, the micro LEDs ML may be arranged at a three-fold pitch distance of the pitch distance of the micro LEDs of the growth substrate 101 in the x-direction and at a one-fold pitch distance thereof in the y-direction.

In the head transfer step, the transfer head part 14 may collectively hold the micro LEDs ML transferred to the carrier substrate C and transfer the same to the pixel substrate FP. The order of the micro LEDs ML transferred to the pixel substrate FP in the head transfer step is not limited. In the present disclosure, as an example, the micro LEDs ML may be transferred to the pixel substrate FP in the order of the first, second, and third micro LEDs ML1, ML2, and ML3. Therefore, the first to third head transfer steps may be performed sequentially.

The transfer head 15 may collectively transfer the first micro LEDs ML1 to the pixel substrate FP in the first head transfer step. Then, the transfer head 15 may perform the second head transfer step. In the second head transfer step, the transfer head 15 may be moved to the right side in the drawing by a distance corresponding to the x-direction pitch distance of the micro LEDs ML with respect to the first micro LEDs ML1 transferred in the first head transfer step, and may collectively transfer the second micro LEDs ML2 to the pixel substrate FP. Then, the transfer head 15 may perform the third head transfer step. In the third head transfer step, the transfer head 15 may be moved to the right side in the drawing by a distance corresponding to the x-direction pitch distance of the micro LEDs ML with respect to the second micro LEDs ML2 transferred in the second head transfer step, and may collectively transfer the third micro LEDs ML3 to the pixel substrate FP.

FIG. 6B is a view illustrating the first, second, and third micro LEDs ML1, ML2, and ML3 transferred to the pixel substrate FP by performing the first to third head transfer steps by the transfer head 15. When, as illustrated in FIG. 6A, the micro LEDs ML transferred to the carrier substrate C in which the seating recesses 11a are formed at a three-fold pitch distance in the x-direction are transferred to the pixel substrate FP by performing the first to third head transfer steps described above, as illustrated in FIG. 6B, a form in which micro LEDs ML of the same type are transferred in the y-direction may be formed. The pixel substrate FP may have an micro LED ML arrangement in which the micro LEDs ML of the same type are arranged in the y-direction, and thus, a form in which a pixel unit is formed in the x-direction may be implemented.

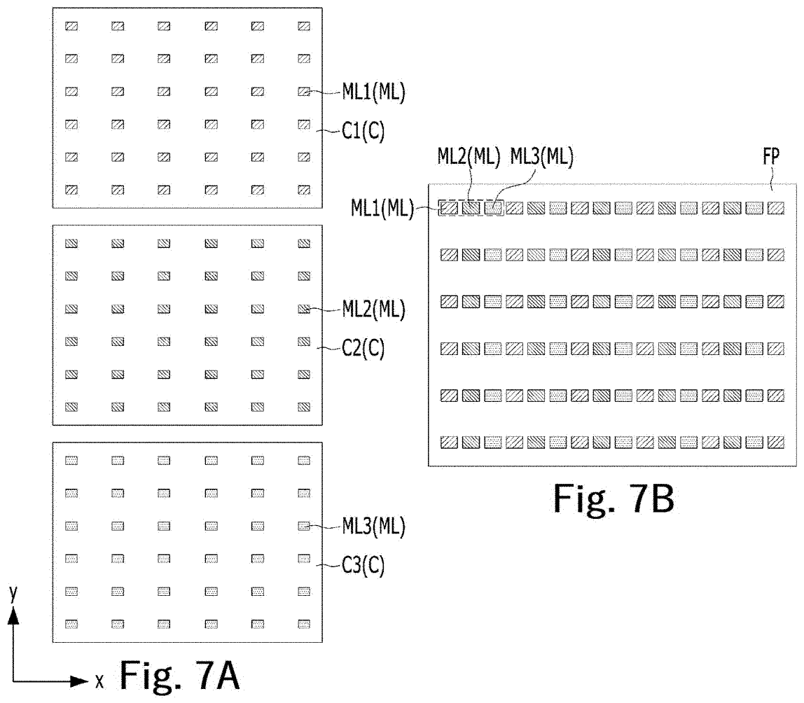

FIG. 7A is a view illustrating micro LEDs ML transferred to a carrier substrate C in which seating recesses 11a are formed at a three-fold pitch distance of the pitch distance of the micro LEDs ML of the growth substrate 101 in the x- and y-directions. The transfer head 15 may collectively transfer respective micro LEDs ML1, ML2, and ML3 to a pixel substrate FP by performing the first to third head transfer steps.

When the seating recesses 11a are formed in the carrier substrate C at a three-fold pitch distance of the pitch distance of the micro LEDs ML of the growth substrate 101 in the x- and y-directions, the micro LEDs ML transferred to the carrier substrate C may be arranged at a three-fold pitch distance in the x- and y-directions. The transfer head 15 may perform the first to third head transfer steps of holding the respective micro LEDs ML1, ML2, and ML3 in this arrangement and transferring the same to the pixel substrate FP.

The transfer head 15 may perform a process of collectively transferring the first, second, and third micro LEDs ML1, ML2, and ML3 in each step, similar to the first to third head transfer steps described with reference to FIGS. 6A and 6B.

FIG. 7B is a view illustrating the pixel substrate FP to which the micro LEDs ML are transferred by the first to a third head transfer steps. In this case, in FIG. 7B, an embodiment in which the transfer head 15 is moved on the pixel substrate FP to the right by a distance corresponding to the x-direction pitch distance of the micro LEDs ML to transfer the micro LEDs ML of the carrier substrate C is illustrated. Therefore, a form in which a pixel unit is not formed in the y-direction of the pixel substrate FP and micro LEDs ML of the same type are arranged at a three-fold pitch distance may be implemented.

In other words, the micro LEDs ML1, ML2, and ML3 arranged on respective carrier substrates C1, C2, and C3 at a three-fold pitch distance in the x- and y-directions are transferred to the pixel substrate FP, so that a form in which a pixel unit is formed in the x-direction may be implemented on the pixel substrate FP.

Although FIG. 7B illustrates a pixel unit formed in the x-direction of the pixel substrate FP, the head transfer step may be additionally performed to implement a form in which a pixel unit is also formed in the y-direction of the pixel substrate FP. In this case, the transfer head 15 may collectively transfer micro LEDs (e.g., the second micro LEDs ML2 to be transferred in the second head transfer step) by being moved downward in the drawing by a distance corresponding to the y-direction pitch distance of the micro LEDs with respect to first transferred micro LEDs (e.g., the first micro LEDs ML1 transferred in the first head transfer step). In the case of implementing a form in which a pixel unit is formed only in the x-direction of the pixel substrate FP, in the additional head transfer step, the micro LEDs (e.g., the second micro LEDs ML2) that are different from the first transferred micro LEDs (e.g., the first micro LEDs ML1) may not be transferred in the y-direction, but micro LEDs (e.g., the first micro LEDs ML1) that are the same type as the first transferred micro LEDs may be transferred in the y-direction. The transfer head 15 may hold the micro LEDs (e.g., the first micro LEDs ML1), may be moved downward in the drawing by a distance corresponding to the y-direction pitch distance of the micro LEDs with respect to the micro LEDs (e.g., the first micro LEDs) first transferred to the pixel substrate FP, and may transfer the micro LEDs (e.g., the first micro LEDs ML1).

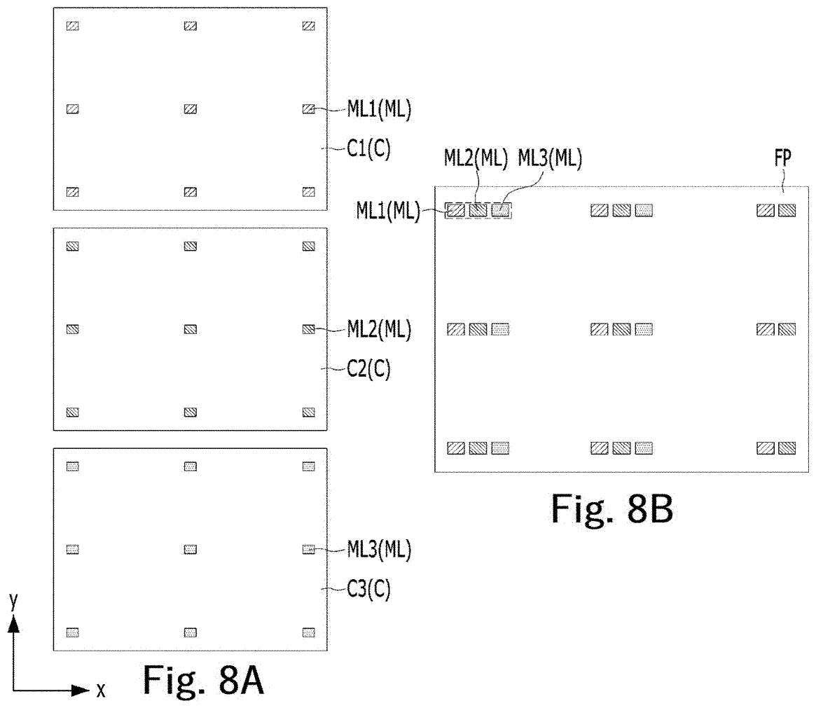

FIG. 8A is a view illustrating micro LEDs ML transferred to a carrier substrate C in which seating recesses 11a are formed at a six-fold pitch distance of the pitch distance of the micro LEDs ML of the growth substrate 101 in the x- and y-directions. The transfer head 15 may collectively transfer respective micro LEDs ML1, ML2, and ML3 to a pixel substrate FP by performing the first to third head transfer steps.

When the seating recesses 11a are formed in the carrier substrate C at a six-fold pitch distance of the pitch distance of the micro LEDs ML of the growth substrate 101 in the x- and y-directions, the micro LEDs ML transferred to the carrier substrate C may be arranged at a six-fold pitch distance in the x- and y-directions. The transfer head 15 may perform the first to third head transfer steps of holding the respective micro LEDs ML1, ML2, and ML3 in this arrangement and transferring the same to the pixel substrate FP.

The transfer head 15 may perform a process of collectively transferring the first, second, and third micro LEDs ML1, ML2, and ML3 in each step, similar to the first to third head transfer steps described with reference to FIGS. 6A and 6B.

FIG. 8B is a view illustrating the pixel substrate FP to which the micro LEDs ML are transferred by the first to a third head transfer steps. In this case, in FIG. 8B, an embodiment in which the transfer head 15 is moved on the pixel substrate FP to the right by a distance corresponding to the x-direction pitch distance of the micro LEDs ML to transfer the micro LEDs ML of the carrier substrate C is illustrated. Therefore, a form in which a pixel unit is not formed in the y-direction of the pixel substrate FP and micro LEDs ML of the same type are arranged at a six-fold pitch distance may be implemented.

Although FIG. 8B illustrates a pixel unit formed in the x-direction of the pixel substrate FP, the head transfer step may be additionally performed to implement a form in which a pixel unit is also formed in the y-direction of the pixel substrate FP. Since the process of additionally performing the head transfer step is the same as that described above with reference to FIG. 7B, a detailed description thereof will be omitted.

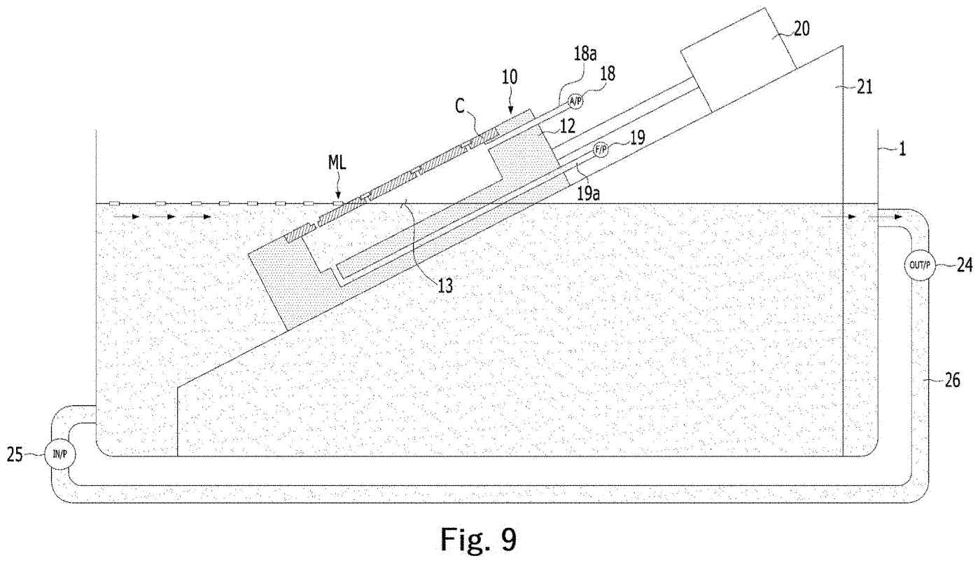

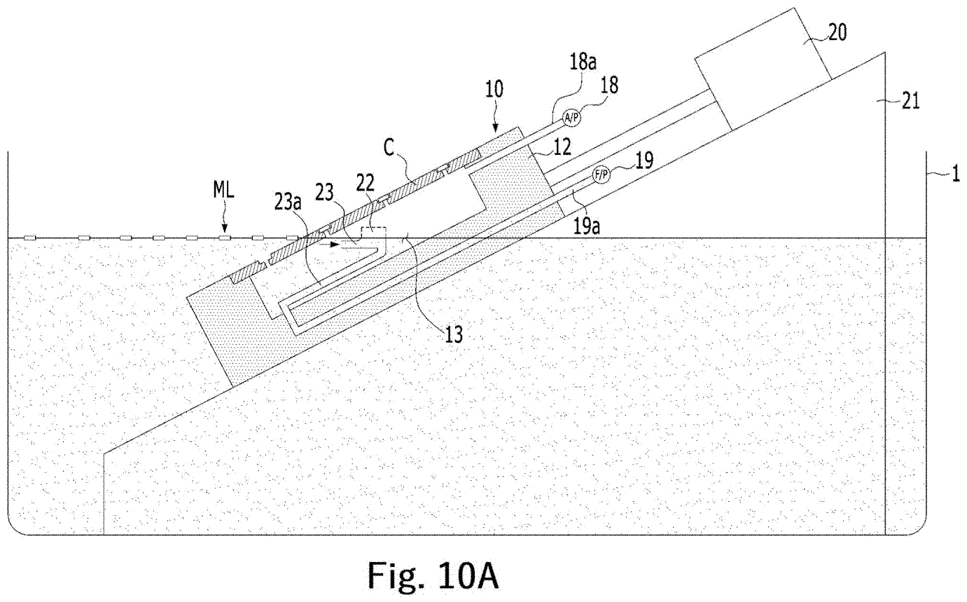

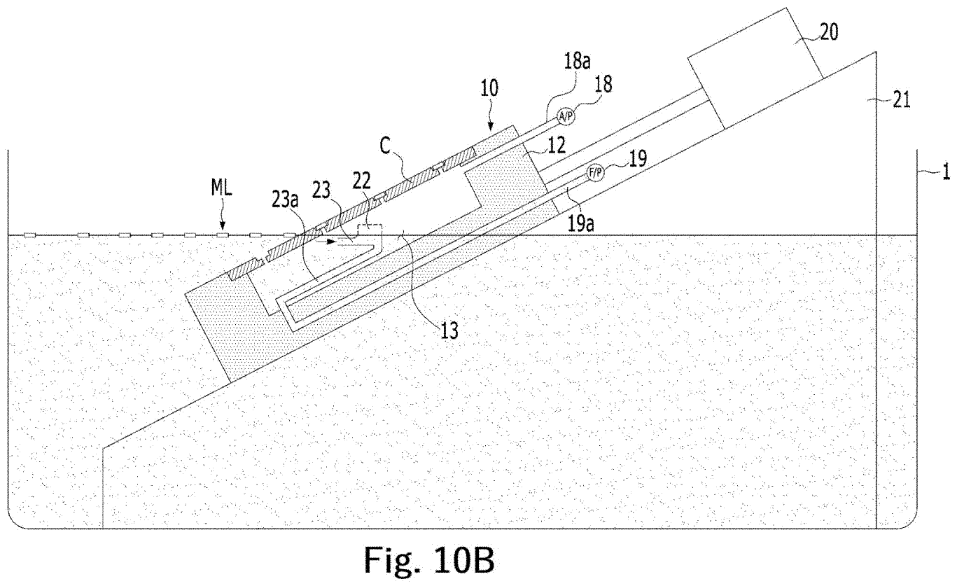

FIGS. 9, 10A, and 10B are views schematically illustrating various embodiments of a fluid transfer step using a carrier part of a micro LED display manufacturing device according to the present disclosure. In this case, the process of performing the fluid transfer step using the carrier part 10 may be the same as that described above with reference to FIG. 4, and there is a difference in that the fluid transfer step is performed with the provision of a separate device for performing the fluid transfer step more efficiently.

FIG. 9 is a view illustrating a process of performing the fluid transfer step with the provision of an in-pump 25 and an out-pump 24 connected to a storage tank 1.

As illustrated in FIG. 9, the in-pump 25 may be provided at a first end of the storage tank 1, and the out-pump 24 may be provided at a second end thereof. The out-pump 24 may function to discharge a fluid in the storage tank 1, and the in-pump 25 may function to allow the fluid discharged from the storage tank 1 through the out-pump 24 to flow back into the storage tank 1.

In the present disclosure, through the provision of the in-pump 25 and the out-pump 24 provided at the first and second ends of the storage tank 1, respectively, the flow direction of the fluid may be effectively formed in the fluid transfer step. In FIG. 9, as an example, an end of the storage tank 1 on the left side in the drawing may be the first end, and an end thereof on the right side in the drawing may be the second end. As illustrated in FIG. 9, the in-pump 25 may be provided on a first outside (on the left side in the drawing) of the storage tank 1, and the out-pump 24 may be provided on a second outside (on the right side in the drawing) of the storage tank 1.

The in-pump 25 and the out-pump 24 may be provided at opposite positions to form the flow direction of the fluid in the storage tank 1. The in-pump 25 and the out-pump 24 may be provided at opposite positions, while having a height difference therebetween. Specifically, as illustrated in FIG. 9, the out-pump 24 for discharging the fluid may be provided at a height close to the fluid surface. This may be to more effectively move micro LEDs ML toward a carrier substrate C by discharging the fluid at a position close to floating micro LEDs ML on the fluid surface.

The out-pump 24 and the in-pump 25 may be operated simultaneously. Therefore, the fluid discharged through a common pipe 26 by the operation of the out-pump 24 may flow back into the storage tank 1 through the common pipe 26. The common pipe 26 may be have a structure connecting the storage tank 1, the out-pump 24 and the in-pump 25 to each other. Therefore, the fluid discharged through the common pipe 26 by the operation of the out-pump 24 may flow back into the storage tank 1 by the operation of the in-pump 25.

The in-pump 25 may be provided at a position opposite to the out-pump 24 with a height difference therebetween. As illustrated in FIG. 9, the in-pump 25 may be provided away from the fluid surface to have a height difference greater than that between the out-pump 24 and the fluid surface. In other words, the in-pump 25 may be provided at a position close to a lower portion of the storage tank 1. The in-pump 25 functions to allow the fluid discharged by the operation of the out-pump 24 to flow back into the storage tank 1. At this time, while the fluid flows into the storage tank 1, vibration may occur on the fluid surface on which the micro LEDs ML float. This vibration may interfere with the movement of the micro LEDs ML floating along the flow direction of the fluid. In addition, a problem wherein the micro LEDs ML are overturned may occur. Therefore, vibration generated by the fluid flowing back into the storage tank 1 through the in-pump 25 may act as a factor that interferes with the fluid transfer step. In order to prevent such a problem, preferably, the in-pump 25 is provided away from the fluid surface at a position adjacent to the lower portion of the storage tank 1.

Meanwhile, in the fluid transfer step, since the in-pump 25 and the out-pump 24 are operated simultaneously, the amount of the fluid may be maintained constant. In other words, even when the fluid is discharged by the out-pump 24 in a fluid transfer process performed with the provision of the in-pump 25 and the out-pump 24, the process in which the fluid flows back into the storage tank 1 by the in-pump 25 along the common pipe 26 may be repeated. Therefore, the fluid transfer process of transferring the micro LEDs ML to the carrier substrate C may be effectively performed by more efficiently forming the flow direction of the fluid while maintaining the amount of the fluid constant.

FIGS. 10A and 10B are views illustrating a process of performing a fluid transfer step with a flow generator 22.

FIG. 10A is a view illustrating micro LEDs ML transferred to at least a part of seating recesses 11a of a carrier substrate C in the fluid transfer step, and FIG. 10B is a view illustrating micro LEDs transferred to all the seating recesses 11a of the carrier substrate C. The lifting position of a carrier part 10 illustrated in FIG. 10B may be higher than that illustrated in FIG. 10A.

First, the fluid transfer step performed with the provision of the flow generator 22 will be described in detail with reference to FIG. 10A.

As illustrated in FIG. 10A, the fluid transfer step may be performed with the provision of the flow generator 22 that floats on the fluid surface like the micro LEDs ML.

The flow generator 22 may generate a flow of the fluid toward the carrier substrate C. When the direction in which the carrier substrate C is located in the drawings of FIGS. 10A and 10B is referred to as the front of the micro LEDs ML, the flow generator 22 may generate the flow of the fluid in front of the micro LEDs ML. In the fluid transfer step described with reference to FIGS. 4 and 9, the flow direction of the fluid is such that the flow of the fluid is generated behind the micro LEDs ML to allow the micro LEDs ML to be moved forward. On the other hand, as illustrated in in FIGS. 10A and 10B, the flow of the fluid may be generated in front of the micro LEDs ML by the flow generator 22. Thus, the micro LEDs ML may be guided to be moved forward along the flow of the fluid.

The flow generator 22 may be provided in the form of a floating body as an example. In the present disclosure, as illustrated in FIGS. 10A and 10B, as an example, a floating body is illustrated and described as being provided as the flow generator 22 in a common chamber 13 of the carrier part 10.

The flow generator 22 provided inside the carrier part 10 may float on the fluid surface like the micro LEDs ML. By the flow generator 22, a flow along which the micro LEDs ML are guided to be moved toward the carrier substrate C may be formed more effectively in front of the micro LEDs ML.

In the case of not providing the flow generator 22, the fluid flowing into the common chamber 13 through vacuum holes 11b may flow into a fluid pump pipe 19a and discharged. In this case, the flow of the fluid may be generated to flow into the fluid pump pipe 19a rather than the seating recesses 11a, so that the process of seating the micro LEDs ML in the seating recesses 11a may be performed relatively inefficiently. However, in the case of performing the fluid transfer step with the provision of the flow generator 22, the fluid flowing into the common chamber 13 may not flow directly into the fluid pump pipe 19a but the flow of thereof is formed by the flow generator 22 so as to flow on the fluid surface along the flow direction of the fluid. Therefore, this may ensure that the micro LEDs ML are more easily seated into the seating recesses 11a.

Referring to FIG. 10A, the flow generator 22 may continuously generate the flow of the fluid into the seating recesses 11a in which the micro LEDs ML are to be seated. Since the flow generator 22 generates the flow of the fluid in front of the micro LEDs ML, the micro LEDs ML may be guided in the vicinity of the seating recesses 11a in which the micro LEDs ML are to be seated toward the seating recesses 11a. Thus, when the micro LEDs ML floating on the fluid surface are positioned corresponding to seating recesses 11a in which the micro LEDs ML are to be seated as the carrier part 10 is lifted, the micro LEDs ML may be easily introduced into the corresponding seating recesses 11a along the flow of the fluid.

In addition, when the flow generator 22 generates the flow of fluid in front of the micro LEDs ML to allow the micro LEDs ML to be introduced into the seating recesses 11a in which the micro LEDs ML are to be seated, introduction of micro LEDs ML, other than the micro LEDs ML to be seated in the seating recesses 11a toward the carrier substrate C may be minimized. This is because the flow generator 22 is provided in the vicinity of the seating recesses 11a in which the micro LEDs ML are to be seated and generates the flow of the fluid to allow the micro LEDs ML close to the seating recesses 11a to be guided to the seating recesses 11a. Therefore, in the present disclosure, in the case of providing the flow generator 22 in the fluid transfer step, this may be more effective in terms of introducing the micro LEDs ML to be seated into the seating recess 11a and minimizing the introduction of other micro LEDs ML toward the carrier substrate C.

In the present disclosure, in the case of providing the flow generator 22, a separate fluid generating means may be used to generate a flow of the fluid behind the micro LEDs ML, and the flow generator 22 may also be used to generate a flow of the fluid in front of the micro LEDs ML. In other words, the flows of the fluid may be generated in the same direction behind and in front of the micro LEDs ML. This may be more effective in terms of moving the micro LEDs ML on the fluid surface along the flow of the flow.

The flow generator 22 may be supported by a support pipe 23 supporting the flow generator 22.

Since the support pipe 23 is a structure that supports the flow generator 22, the support pipe 23 may be provided inside the carrier part 10 together with the flow generator 22.

The support pipe 23 may support the flow generator 22 and may be configured to be in communication with a fluid pump 19 that sucks and discharges the fluid. Since the support pipe 23 supports the flow generator 22 floating on the fluid surface, the support pipe 23 may float inside the fluid so as to be close to the fluid surface and may be provided in the vicinity of the seating recesses 11a in which the micro LEDs ML are to be seated.

In this case, the positions of the support pipe 23 and the flow generator 22 may not be changed, but the positions of the seating recesses 11a in which the micro LEDs ML are to be seated may be changed according to an inclination angle that the carrier substrate C forms with the fluid as the carrier part 10 is lifted. The support pipe 23 and the flow generator 22 may float in place and generate the flows of the fluid in the vicinity of the seating recesses 11a changing their position so that the micro LEDs ML may be efficiently introduced into the seating recesses 11a. The support pipe 23 may more effectively generate the flow of the fluid to the seating recesses 11a by sucking the fluid through an opening.

The support pipe 23 may be connected to a telescopic pipe 23a that expands and contracts in conjunction with lifting of the carrier part 10.

The telescopic pipe 23a may connect the support pipe 23 and the fluid pump pipe 19a to each other so that the fluid sucked through the opening of the support pipe 23 may be discharged.

FIG. 10B is a view illustrating a state in which the carrier part illustrated in FIG. 10A is lifted to a position higher than that illustrated in FIG. 10A.

As illustrated in FIG. 10B, the positions of the seating recesses 11a in which the micro LEDs ML are to be seated may be changed according to the inclination angle that the carrier substrate C forms with the fluid as the carrier part 10 is lifted. In this case, the positions of the support pipe 23 and the flow generator 22 may remain unchanged in their position, and the flows of the fluid for introducing the micro LEDs ML into the seating recesses 11a positioned in the vicinity of the support pipe 23 may be generated.

As such, in the fluid transfer step, through the provision of the flow generator 22, the flow of the fluid may be generated in front of the micro LEDs ML. In this case, the support pipe 23 supporting the flow generator 22 may float inside the fluid so as to be close to the fluid surface at a position under the flow generator 22. Since the flow generator 22 and the support pipe 23 float in place, the flow generator 22 and the support pipe 23 may be always located in the vicinity of the seating recesses 11a in which the micro LEDs ML are to be seated, without being influenced by lifting of the carrier part 10. With this structure, the process of transferring the micro LEDs ML to the carrier substrate C in the fluid transfer step may be more effectively performed.

As described above, in the present disclosure, the micro LEDs ML fabricated on the growth substrate 101 may be fluidly transferred through the fluid transfer step according to various embodiments. In the present disclosure, in the fluid transfer step, the micro LEDs ML may be transferred to the carrier substrate C by supplementing problems (specifically, non-uniform micro LED ML light emission characteristics, micro LED ML damage, and transfer of defective micro LEDs to the carrier substrate C) that may occur in the growth substrate 101. Then, in the head transfer step, the micro LEDs ML of the carrier substrate C may be rapidly and collectively transferred to the pixel substrate FP. Thus, a pixel unit may be formed in the pixel substrate FP.

Specifically, the present disclosure may perform the steps of: inserting first micro LEDs ML1 fabricated and individualized on a first growth substrate 101a into a first storage tank; holding the first micro LEDs ML1 inserted into the first storage tank onto the first carrier substrate C1; inserting second micro LEDs ML2 fabricated and individualized on a second growth substrate 101b into a second storage tank; holding the second micro LEDs ML2 inserted into the second storage tank onto a second carrier substrate C2; inserting third micro LEDs ML3 fabricated and individualized on a third growth substrate 101c into a third storage tank; holding the third micro LEDs ML3 inserted into the third storage tank onto a third carrier substrate C3; holding, by a transfer head 15, the first micro LEDs ML1 of the first carrier substrate C1 on which the first micro LEDs ML1 are seated and transferring the same to a pixel substrate FP; holding, by the transfer head 15, the second micro LEDs ML2 of the second carrier substrate C2 on which the second micro LEDs ML2 are seated and transferring the same to the pixel substrate FP; and holding, by the transfer head 15, the third micro LEDs ML3 of the third carrier substrate C3 on which the third micro LEDs ML3 are seated and transferring the same to the pixel substrate FP, so that the first, second, third micro LEDs ML1, ML2, and ML3 may constitute a pixel unit on the pixel substrate FP.

In the present disclosure, by performing the fluid transfer step and the head transfer step in an appropriate order among the steps for manufacturing a micro LED display as described above, a hybrid transfer process that simultaneously utilizes the advantages of each transfer step (e.g., in the case of the fluid transfer step, the problem in the growth substrate 101 is supplemented, and in the case of the head transfer step, a rapid transfer process) may be implemented. As a result, a micro LED display of good quality may be efficiently manufactured.

The present disclosure may perform a laminating step of laminating, with films 34 and 35, respectively, upper and lower portions of each of the carrier substrate C to which the micro LEDs ML of the growth substrate 101 are transferred by the fluid transfer step, and the pixel substrate FP to which the micro LEDs ML of the carrier substrate C are transferred by the head transfer step. The micro LEDs ML transferred to the carrier substrate C and/or the pixel substrate FP may be covered with films on upper and lower portions thereof by the laminating step, so that a problem of particle adhesion to the surfaces of the micro LEDs ML may be prevented.

In order to perform the laminating step as described above, the present disclosure may include a laminating part 36. The laminating part 36 may laminate the upper and lower portions of each of the carrier substrate C and the pixel substrate FP with the films 34 and 35, respectively, under a vacuum atmosphere. Therefore, the laminating part 36 may be configured as a suitable means capable of forming a vacuum atmosphere.

Specifically, when the laminating part 36 laminates the carrier substrate C to which the micro LEDs ML of the growth substrate 101 are transferred, the upper portion of the carrier substrate C may be laminated with the upper film 34, the lower portion thereof may be laminated with the lower film 35. In this case, particles that may adhere to the surfaces of the micro LEDs ML before the subsequent process may be prevented.

In addition, when the laminating part 36 laminates the pixel substrate FP to which the micro LEDs ML are transferred, the upper portion of the pixel substrate FP may be laminated with the upper film 34 and the lower portion thereof may be laminated with the lower film 35. In this case, particles that may adhere to the surfaces of the micro LEDs ML before the subsequent process may be prevented.

The particles on the surfaces of the micro LEDs ML may act as a factor that may cause defective products. In the present disclosure, such a problem may be prevented by the laminating step.

In order to laminate the upper and lower portions of the carrier substrate C to which the micro LEDs ML of the growth substrate 101 are transferred with the films, the laminating step may be performed between the fluid transfer step and the head transfer step.

In addition, in order to laminate the micro LEDs ML transferred to the pixel substrate FP before transfer to the circuit board 301, the laminating step may be performed after the head transfer step and before the step of transferring the micro LEDs ML of the pixel substrate FP to the circuit board 301.

In other words, the laminating step may be performed a plurality of times in a different order in the process of manufacturing a micro LED display. However, when the pixel substrate FP has a circuit part and thus functions as the circuit board 301, the laminating step may be performed only in the fluid transfer step.

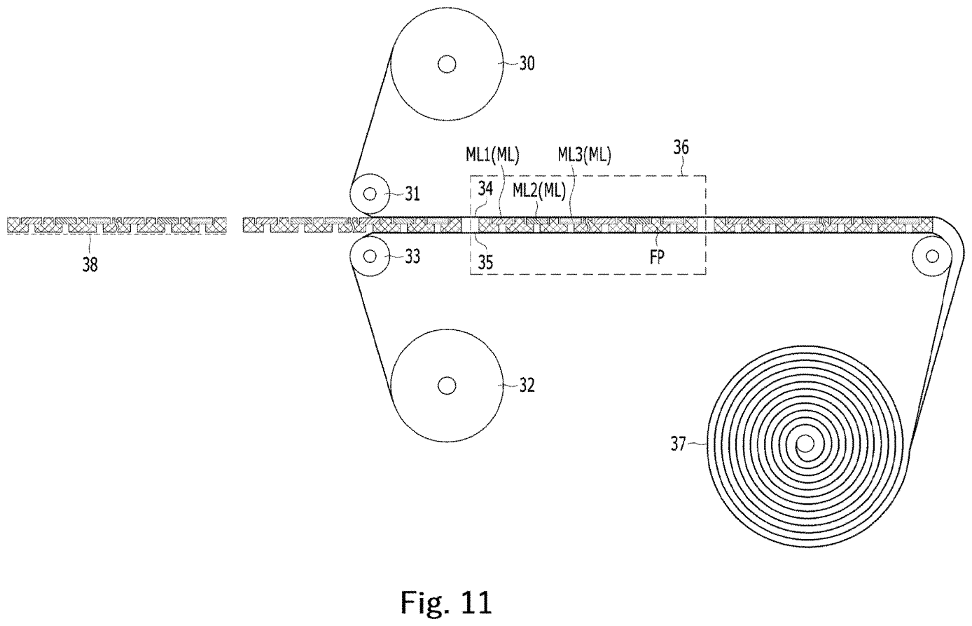

Hereinafter, the laminating step will be described in detail with reference to FIG. 11. FIG. 11 is a view schematically illustrating the laminating step performed by the laminating part 36. In this case, in FIG. 11, as an example, the pixel substrate FP is illustrated as being laminated by the laminating step. Therefore, it is illustrated that the first, second, third micro LEDs ML1, ML2, and ML3 constitute a pixel unit on the pixel substrate FP.

As illustrated in FIG. 11, the pixel substrate FP may be provided on the laminating process line 38 to undergo the laminating step. An upper reel 30 on which the upper film 34 is reeled and an upper guide 31 guiding the upper film 34 of the upper reel 30 to the surfaces of the micro LEDs ML may be provided above the laminating process line 38. In addition, a lower reel 32 on which the lower film 35 is reeled and a lower guide for guiding the lower film 35 of the lower reel 32 to a lower surface of the pixel substrate FP may be provided below the laminating process line 38. When the substrate to be laminated in the laminating step is the carrier substrate C, the upper guide 31 may guide the upper film 34 of the upper reel 30 to the surfaces of the micro LEDs ML, and the lower guide 33 may guide the lower film of the lower reel 32 to a lower surface of the carrier substrate C.

The upper and lower films 34 and 35 reeled on the upper and lower reels 30 and 32 may be brought into contact with the upper and lower portions of the pixel substrate FP provided on the laminating process line 38 by the upper and lower guides 31 and 33, respectively. Then, the pixel substrate FP may be moved to the laminating part 36, and the films 34 and 35 may be adhered to the upper and lower portions of the pixel substrate FP under a vacuum atmosphere formed by the laminating part 36.

The pixel substrate FP may be made of a flexible material in the laminating step, and may undergo a reeling step of reeling the pixel substrate FP laminated with the upper and lower films 34 and 35 onto a main reel 37.

The pixel substrate FP having undergone the reeling step may be transferred to undergo a process for bonding the micro LEDs ML of the pixel substrate FP to the circuit board 301. In this case, since the pixel substrate FP is reeled on the main reel 37, convenient transfer may be possible. In addition, since the pixel substrate FP is reeled on the main reel 37 with the upper and lower films 34 and 35 adhered thereto, a contamination problem due to particles may be prevented.

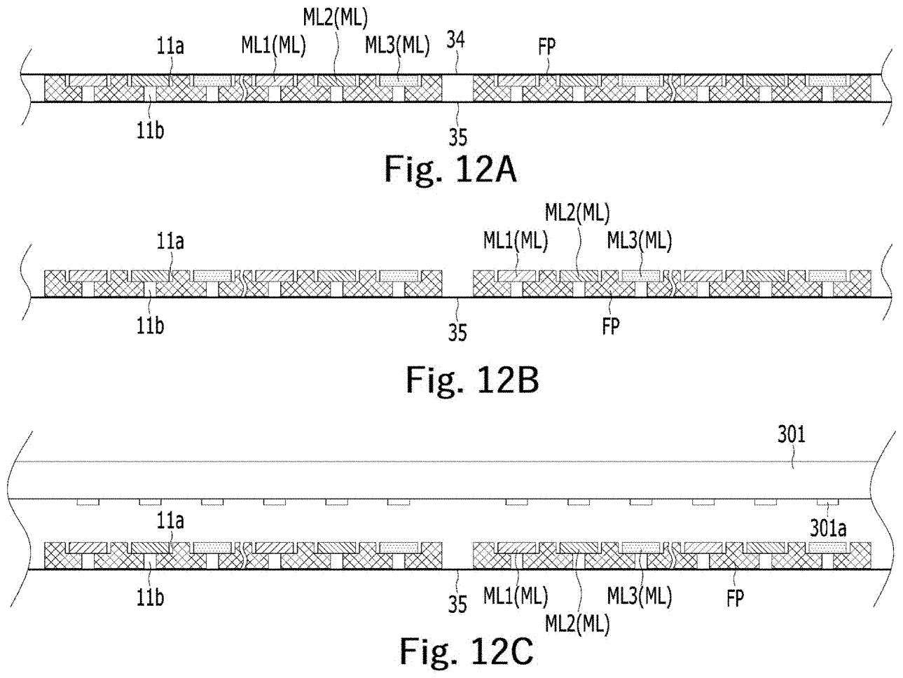

FIGS. 12A, 12B, and 12C are views schematically illustrating a process of bonding the micro LEDs ML of the pixel substrate FP to the circuit board 301.

The process of bonding the micro LEDs ML of the pixel substrate FP laminated in the laminating step described above with reference to FIG. 11 to the circuit board 301 may include: an upper film removing step of removing the upper film 34 of the pixel substrate FP laminated with the upper film 34 and the lower film 35; a circuit board disposing step of disposing the circuit board 301 on the pixel substrate FP; a micro LED bonding step of bonding the micro LEDs ML of the pixel substrate FP to the circuit board 301; and a lower film removing step of removing the lower film 35 from the pixel substrate FP.

First, as illustrated in FIG. 12A, the pixel substrate FP reeled on the main reel 37 may be unreeled and stretched again horizontally. This may be to efficiently perform a process of bonding the pixel substrate FP with a bonding layer 301a of the circuit board 301.

Then, as illustrated in FIG. 12B, the upper film removing step of removing the upper film 34 may be performed. The upper film 34 may be removed by any suitable means for removing the upper film 34 from the surface of the micro LEDs ML.

Since the micro LEDs ML are in a state of being fixed to the seating recesses 11a by vacuum force as the vacuum holes 11b are sealed by the lower film 35, even when the upper film 34 is removed, the micro LEDs ML may be maintained in a fixed state.

Then, as illustrated in FIG. 12C, the circuit board disposing step of disposing the circuit board 301 on the pixel substrate FP may be performed. On the circuit board 301 disposed in the circuit board disposing step, bonding layers 301a may be provided at the same pitch distance as the micro LEDs ML of the pixel substrate FP in which a pixel unit is formed.

The circuit board 301 disposed in the circuit board disposing step may be lowered to be brought into contact with the micro LEDs ML of the pixel substrate FP. Then, a process of transferring the micro LEDs ML of the pixel substrate FP to the circuit board 301 may be performed. In this case, the pixel substrate FP from which the upper film 34 is removed may be in a state of having the lower film 35 adhered to the lower portion thereof. The micro LEDs ML and the lower film 35 may be in a state of being fixed by vacuum pressure of the vacuum holes 11b provided between the micro LEDs ML and the lower film 35. Therefore, when the micro LEDs ML are brought into contact with the bonding layers 301a of the circuit board 301, the vacuum pressure of the vacuum holes 11b of the pixel substrate FP may be released, so that the lower film 35 may be removed and the micro LEDs ML may be detached from the seating recesses 11a of the pixel substrate FP. Through this process, the micro LEDs ML of the pixel substrate FP may be transferred to the circuit board 301.

Meanwhile, when the carrier substrate C is laminated in the laminating step, the same process as the process of laminating the pixel substrate FP described with reference to FIGS. 11 to 12C may be performed.

Specifically, when the laminating part 36 laminates the carrier substrate C to which the micro LEDs ML of the growth substrate 101 are transferred, the carrier substrate C may be provided on the laminating process line 38. The upper and lower films 34 and 35 reeled on the upper and lower reels 30 and 32 may be brought into contact with the upper and lower portions of the carrier substrate C provided on the laminating process line 38 by the upper and lower guides 31 and 33, respectively. Then, the pixel substrate FP may be moved to the laminating part 36, and the films 34 and 35 may be adhered to the upper and lower portions of the carrier substrate C under a vacuum atmosphere formed by the laminating part 36.

T carrier substrate C may be made of a flexible material in the laminating step, and may undergo a reeling step of reeling the carrier substrate C laminated with the upper and lower films 34 and 35 onto the main reel 37.

The carrier substrate C having undergone the reeling step may be unreeled and stretched horizontally to undergo the head transfer step. In the head transfer step, a process of collectively transferring the micro LEDs ML of the carrier substrate C to the pixel substrate FP may be performed.

On the other hand, the carrier substrate C having undergone the reeling step may be unreeled and stretched horizontally to undergo a process for bonding the micro LEDs ML of the carrier substrate C to the circuit board 301. The process of bonding the micro LEDs ML of the carrier substrate C to the circuit board 301 may be the same as that of bonding the micro LEDs ML of the pixel substrate FP to the circuit board 301 described above with reference to FIGS. 12A, 12B, and 12C.

The micro LEDs ML of the pixel substrate FP with a pixel unit described above with reference to FIGS. 12A, 12B, and 12C may be collectively bonded to the circuit board 301. On the other hand, when the micro LEDs ML of the carrier substrate C having undergone the reeling step are bonded to the circuit board 301, a process of bonding the micro LEDs ML1, ML2, and ML3 of the respective carrier substrates C1, C2, and C3 to the circuit board 301 may be performed.

Specifically, a process of bonding the first micro LEDs ML1 of the first carrier substrate C1 to the circuit board 301 by unreeling and stretching horizontally the first carrier substrate C1 having undergone the reeling step may be performed.

Then, in the same manner, a process of bonding the respective micro LEDs ML2 and ML3 of the second carrier substrate C2 and the third carrier substrate C3 to the circuit board 301 may be performed. By the bonding process performed a plurality of times, a pixel unit may be formed in the circuit board 301.

When the micro LEDs ML of the carrier substrate C are directly bonded to the circuit board 301, preferably, the pitch distance of the seating recesses 11a of the carrier substrate C in at least one of the x- and y-directions is a three-fold pitch distance. Thus, the micro LEDs ML1, ML2, and ML3 of the respective carrier substrates C1, C2, and C3 may be bonded to the circuit board 301, so that a pixel unit may be efficiently formed.

In the present disclosure, through the hybrid transfer process in which the fluid transfer step and the head transfer step are combined as described above, the micro LED ML transfer process for manufacturing a micro LED display may be performed more efficiently. In addition, in the micro LED ML transfer process, a factor (specifically, particles adhered to the surfaces of the micro LEDs) that may cause defects in the process of moving a substrate (e.g., the carrier substrate C or the pixel substrate FP) to which the micro LEDs ML are transferred may be prevented. As a result, a micro LED display of good quality may be manufactured more effectively.

As described above, the present disclosure has been described with reference to the exemplary embodiments. However, those skilled in the art will appreciate that various modifications, additions and substitutions are possible, without departing from the scope and spirit of the present disclosure as disclosed in the accompanying claims.

### DESCRIPTION OF THE REFERENCE NUMERALS IN THE DRAWINGS

| | |
|---|---|
| 1: storage tank | |
| 10: carrier part | 14: transfer head part |
| 16: vision tester | 18: air pump |
| 19: fluid pump | 21: sliding part |
| 22: flow generator | 24: out-pump |
| 25: in-pump | |
| 36: laminating part | |

1. A micro LED display manufacturing device, comprising:
a carrier part including a carrier substrate onto which micro LEDs of the same type inserted into a storage tank in which a fluid is stored are held at positions spaced apart a predetermined pitch distance; and
a transfer head part transferring the micro LEDs on the carrier substrate to a pixel substrate outside the storage tank.

2. The micro LED display manufacturing device of claim 1, wherein the carrier substrate is configured to be lifted while forming an inclination angle with the fluid of the storage tank.

3. The micro LED display manufacturing device of claim 2, wherein the carrier substrate comprises:
a seating recess in which each of the micro LEDs is seated;
a non-seating region where no micro LEDs are seated; and
a vacuum hole formed in a lower portion of the seating recess.

4. The micro LED display manufacturing device of claim 3, wherein when the fluid is hydrophilic, a hydrophobic layer is formed on a surface of the non-seating region, and when the fluid is hydrophobic, a hydrophilic layer is formed thereon.

5. The micro LED display manufacturing device of claim 1, further comprising:
a dryer drying a surface of the carrier part.

6. The micro LED display manufacturing device of claim 1, further comprising:
a vision tester provided above the carrier part,
wherein the vision tester tests whether each of the micro LEDs is seated in a seating recess.

7. The micro LED display manufacturing device of claim 2, further comprising:
a sliding part supporting a lower portion of the carrier part as the lower portion of the carrier part slides therealong.

8. The micro LED display manufacturing device of claim 2, further comprising:
a driving part lifting the carrier part while maintaining the inclination angle constant.

9. The micro LED display manufacturing device of claim 2, further comprising:
a driving part rotating the carrier part so that the inclination angle is reduced.

10. The micro LED display manufacturing device of claim 1, further comprising:
a flow generator generating a flow of the fluid toward the carrier substrate.

11. The micro LED display manufacturing device of claim 1, further comprising:
a laminating part laminating an upper portion of the carrier substrate with an upper film and laminating a lower portion of the carrier substrate with a lower film.

12. The micro LED display manufacturing device of claim 1, wherein the carrier part comprises:
a carrier substrate having a seating recess in which each of the micro LEDs is seated, a non-seating region where no micro LEDs are seated, and a vacuum hole formed in a lower portion of the seating recess; and
a support body detachably coupled to the carrier substrate to support the carrier substrate under the carrier substrate, and including a common chamber in communication with a plurality of vacuum holes.

13. The micro LED display manufacturing device of claim 12, further comprising:
an air pump that is in communication with the common chamber and sucks and discharges air inside the common chamber.

14. The micro LED display manufacturing device of claim 12, further comprising:
a vacuum pressure measuring device measuring pressure in the common chamber so that when it is determined that the pressure in the common chamber reaches a reference pressure, the carrier part is lifted.

15. The micro LED display manufacturing device of claim 13, further comprising:
the air pump provided at a first side of the common chamber to suck and discharge air in the common chamber; and
a fluid pump provided at a second side of the common chamber to suck and discharge the fluid in the common chamber.

16. A method of manufacturing a micro LED display, the method comprising:
holding micro LEDs of the same type inserted into a storage tank in which a fluid is stored onto a carrier substrate at positions spaced apart a predetermined pitch distance; and
transferring the micro LEDs seated on the carrier substrate to a pixel substrate outside of the storage tank.

17. The method of claim 16, wherein in the holding of micro LEDs of the same type, the micro LEDs inserted into the storage tank are composed of only normal micro LEDs.

18. The method of claim 16, wherein in the holding of micro LEDs of the same type, at least one of upper and lower surfaces of each of the micro LEDs is treated to be hydrophobic or hydrophilic so that the micro LED is maintained in a forward direction while floating on a fluid surface.

19. The method of claim 16, wherein in the holding of micro LEDs of the same type, at least one of upper and lower surfaces of each of the micro LEDs has a high density than the other one so that the micro LED is maintained in a forward direction while floating on a fluid surface.

20. The method of claim 16, wherein the holding of micro LEDs of the same type comprises: testing whether each of the micro LEDs is seated in a seating recess of the carrier substrate.

21. The method of claim 16, wherein in the holding of micro LEDs of the same type, the carrier substrate is lifted while forming an inclination angle with the fluid.

22. The method of claim 20, wherein the carrier substrate repeats lifting and lowering operations at the same inclination angle.

23. The method of claim 16, wherein the transferring of the micro LEDs comprises:
holding, by a transfer head, first micro LEDs of a first carrier substrate on which the first micro LEDs are seated and transferring the first micro LEDs to the pixel substrate;
holding, by the transfer head, second micro LEDs of a second carrier substrate on which the second micro LEDs are seated and transferring the second micro LEDs to the pixel substrate; and
holding, by the transfer head, third micro LEDs of a third carrier substrate on which the third micro LEDs are seated and transferring the third micro LEDs to the pixel substrate,
wherein the first to third micro LEDs constitute a pixel unit in the pixel substrate.

24. The method of claim 16, further comprising:
laminating an upper portion of the carrier substrate with an upper film and laminating a lower portion of the carrier substrate with a lower film.

25. The method of claim 24, wherein the carrier substrate is made of a flexible material,
wherein the method further comprises: reeling the carrier substrate laminated with the upper and lower films onto a main reel.

26. A method of manufacturing a micro LED display, the method comprising:
removing an upper film of a pixel substrate laminated with the upper film and a lower film;
disposing a circuit board on the pixel substrate;
bonding micro LEDs of the pixel substrate to the circuit board; and
removing the lower film of the pixel substrate.

27. A method of manufacturing a micro LED display, the method comprising:
inserting first micro LEDs fabricated and individualized on a first growth substrate into a first storage tank;
holding the first micro LEDs inserted into the first storage tank onto a first carrier substrate;
inserting second micro LEDs fabricated and individualized on a second growth substrate into a second storage tank;
holding the second micro LEDs inserted into the second storage tank onto a second carrier substrate;
inserting third micro LEDs fabricated and individualized on a third growth substrate into a third storage tank;
holding the third micro LEDs inserted into the third storage tank onto a third carrier substrate;
holding, by a transfer head, the first micro LEDs of the first carrier substrate on which the first micro LEDs are seated and transferring the first micro LEDs to a pixel substrate;
holding, by the transfer head, the second micro LEDs of the second carrier substrate on which the second micro LEDs are seated and transferring the second micro LEDs to the pixel substrate; and
holding, by the transfer head, the third micro LEDs of the third carrier substrate on which the third micro LEDs are seated and transferring the third micro LEDs to the pixel substrate,
wherein the first to third micro LEDs constitute a pixel unit in the pixel substrate.
